(19) United States
(12) Patent Application Publication
(10) Pub. No.: US 2025/0234593 A1
(43) Pub. Date: Jul. 17, 2025

(54) SEMICONDUCTOR STRUCTURE WITH BONDING STRUCTURE AND METHOD FOR MANUFACTURING THE SAME

(71) Applicant: TAIWAN SEMICONDUCTOR MANUFACTURING COMPANY, LTD., Hsinchu (TW)

(72) Inventors: Han-Jong Chia, Hsinchu City (TW); Ji Cui, Bolingbrook, IL (US)

(73) Assignee: TAIWAN SEMICONDUCTOR MANUFACTURING COMPANY, LTD., Hsinchu (TW)

(21) Appl. No.: 18/414,245

(22) Filed: Jan. 16, 2024

(51) Int. Cl. H01L 29/423; H01L 21/8238; H01L 23/522; H01L 23/528; H01L 27/092; H01L 29/06; H01L 29/417; H01L 29/66; H01L 29/775; H01L 29/786

(52) U.S. Cl. CPC H10D 30/6735; H01L 23/5226; H01L 23/5283; H10D 30/43; H10D 30/6729; H10D 30/6757; H10D 62/121; H10D 64/017; H10D 84/0167; H10D 84/0186; H10D 84/038; H10D 84/85

(57) ABSTRACT

A semiconductor structure and a formation method are provided. The semiconductor structure includes a first transistor, and the first transistor includes a first channel layer and a first gate structure. The semiconductor transistor further includes a second transistor. The second transistor includes a second channel layer and a second gate structure. The semiconductor transistor further includes a bonding structure vertically sandwiched between the first transistor and the second transistor. The bonding structure includes a first dielectric bonding layer attached to the first gate structure and a first conductive bonding structure formed through the first dielectric bonding layer. The bonding structure further includes a second dielectric bonding layer attached to the first dielectric bonding layer and the second gate structure and a second conductive bonding structure formed through the second dielectric bonding layer and bonded to the first conductive bonding structure.

### BACKGROUND

The electronics industry is experiencing ever-increasing demand for smaller and faster electronic devices that are able to perform a greater number of increasingly complex and sophisticated functions. Accordingly, there is a continuing trend in the semiconductor industry to manufacture low-cost, high-performance, and low-power integrated circuits (ICs). So far, these goals have been achieved in large part by scaling down semiconductor IC dimensions (e.g., minimum feature size) and thereby improving production efficiency and lowering associated costs. However, such miniaturization has introduced greater complexity into the semiconductor manufacturing process. Thus, the realization of continued advances in semiconductor ICs and devices calls for similar advances in semiconductor manufacturing processes and technology.

Recently, complementary FET (CFET) have been introduced. In a CFET structure, an nMOS device may be stacked on top of a pMOS device, so that the effective channel width of the resulting device may be further maximized. However, integration of fabrication of the CFET devices can be challenging.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1A illustrates a diagrammatic perspective view of a transistor with a bonding structure formed over the transistor in accordance with some embodiments.

FIG. 1B illustrates a diagrammatic perspective view of a CFET structure, including a top transistor and a bottom transistor in accordance with some embodiments.

FIG. 1C illustrates a cross-section view of a package structure in accordance with some embodiments.

FIG. 2A illustrates a diagrammatic perspective view of a transistor with a bonding structure formed over the transistor in accordance with some embodiments.

FIG. 2B illustrates a diagrammatic perspective view of a CFET structure, including a top transistor and a bottom transistor in accordance with some embodiments.

FIG. 2C illustrates a cross-section view of a package structure, including the CFET structure, in accordance with some embodiments.

FIG. 3A illustrates a diagrammatic perspective view of a transistor with a bonding structure formed over the transistor in accordance with some embodiments.

FIG. 3B illustrates a diagrammatic perspective view of a CFET structure, including a top transistor and a bottom transistor in accordance with some embodiments.

FIG. 3C illustrates a cross-section view of a package structure, including the CFET structure, in accordance with some embodiments.

FIG. 4A illustrates a diagrammatic perspective view of a transistor with a bonding structure formed over the transistor in accordance with some embodiments.

FIG. 4B illustrates a diagrammatic perspective view of a CFET structure, including a top transistor and a bottom transistor in accordance with some embodiments.

FIG. 4C illustrates a cross-section view of a package structure, including the CFET structure, in accordance with some embodiments.

FIG. 5A illustrates a diagrammatic perspective view of a CFET structure, including a top transistor and a bottom transistor in accordance with some embodiments.

FIG. 5B illustrates a cross-section view of a package structure in accordance with some embodiments.

FIG. 6A illustrates a diagrammatic perspective view of a CFET structure, including a top transistor and a bottom transistor in accordance with some embodiments.

FIG. 6B illustrates a cross-section view of a package structure in accordance with some embodiments.

FIG. 7A illustrates a diagrammatic perspective view of a CFET structure, including a top transistor and a bottom transistor, in accordance with some embodiments.

FIG. 7B illustrates a cross-section view of a package structure in accordance with some embodiments.

FIG. 8A illustrates a diagrammatic perspective view of a CFET structure, including a top transistor and a bottom transistor, in accordance with some embodiments.

FIG. 8B illustrates a cross-section view of a package structure in accordance with some embodiments.

FIG. 9 illustrates a diagrammatic perspective view of an intermediate stage of manufacturing the CFET structure in accordance with some embodiments.

FIGS. 10A-1, 10B-1, 10C-1, 10D-1, 10E-1, 10F-1, 10G-1, 10H-1, 10A-2, 10B-2, 10C-2, 10D-2, 10E-2, 10F-2, 10G-2, 10H-2, 10A-3, 10B-3, 10C-3, 10D-3, 10E-3, 10F-3, 10G-3, 10H-3, 10A-4, 10B-4, 10C-4, 10D-4, 10E-4, 10F-4, 10G-4, and 10H-4 illustrate the cross-sectional views of intermediate stages of manufacturing the CFET structure shown along line Y_{SD1}-Y_{SD1′} (i.e. in the Y direction), Y_{MG}-Y_{MG′} (i.e. in the Y direction), Y_{SD2}-Y_{SD2′} (i.e. in the Y direction), and X-X′ (i.e. in the X direction) in FIG. 9, respectively, in accordance with some embodiments.

FIGS. 11A to 11H illustrate the cross-sectional views of intermediate stages of manufacturing the package structure in accordance with some embodiments.

FIG. 12 illustrates a cross-sectional view of an intermediate stage of manufacturing the package structure 300b in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Some variations of the embodiments are described. Throughout the various views and illustrative embodiments, like reference numerals are used to designate like elements. It should be understood that additional operations can be provided before, during, and after the method, and some of the operations described can be replaced or eliminated for other embodiments of the method.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The nanostructure transistors (e.g. nanosheet transistors, nanowire transistors, multi-bridge channel transistors, nano-ribbon FET, and gate all around (GAA) transistors) described below may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, smaller pitches than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the nanostructures.

Embodiments of the disclosure may relate to package structures such as three-dimensional (3D) packaging, 3D-IC devices, and 2.5D packaging. Embodiments of the disclosure form a package structure including a substrate that carries one or more dies or packages and a protective element (such as a protective lid) aside the dies or packages. The protective element may also function as a warpage-control element and/or heat dissipation element. Other features and processes may also be included. For example, testing structures may be included to aid in the verification testing of the 3D packaging, 3DIC devices, and/or 2.5 D packaging. The testing structures may include, for example, test pads formed in a redistribution layer or on a substrate that allows testing to be conducted using probes or probe cards and the like. Verification testing may be performed on intermediate structures as well as the final structure. Additionally, the structures and methods disclosed herein may be used in conjunction with testing methodologies that incorporate intermediate verification of known good dies to increase the yield and decrease costs.

Complementary metal-oxide-semiconductor field effect transistors (CMOSFET or CFET) are used in the semiconductor industry due to their high noise immunity and low static power consumption. A CFET may include an n-type transistor and a p-type transistor. In some embodiments, the n-type transistor and the p-type transistor are vertically oriented to form a CFET structure with a top transistor stacked over a bottom transistor.

The two vertically oriented transistors may be formed by a monolithic process, a sequential process, or in separated processes. However, if the vertically oriented transistors are formed by a monolithic process, the manufacturing processes may be relatively complicated. If the vertically oriented transistors are formed by a sequential process, the thermal processes performed during the manufacturing processes may undermine the performance of the elements formed in the previous processes.

Accordingly, in some embodiments of the present application, two vertically oriented transistors are formed separately and are bonded together afterwards, so that the manufacturing processes may be simplified. In addition, unlike those formed by the sequential processes, the transistors will not be damaged due to the thermal processes performed after their formation. Therefore, the performance of the resulting device may be improved.

More specifically, the transistors may be formed over separated wafers, and the wafers with the transistors having different conductive types may be bonded together through hybrid bonding, including dielectric-to-dielectric bonding and metal-to-metal bonding. That is, the CFET structure may be formed by bonding a top transistor on a first wafer to a bottom transistor on a second wafer through a hybrid bonding structure.

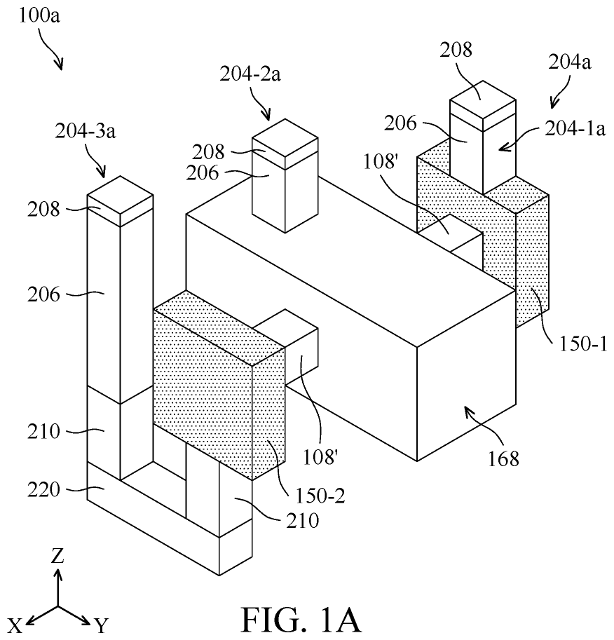

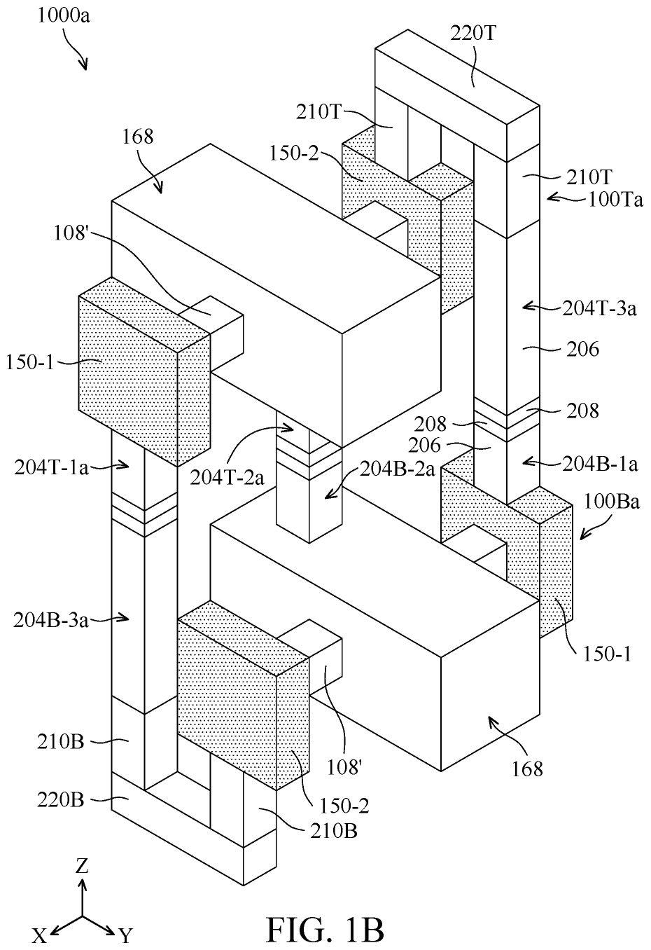

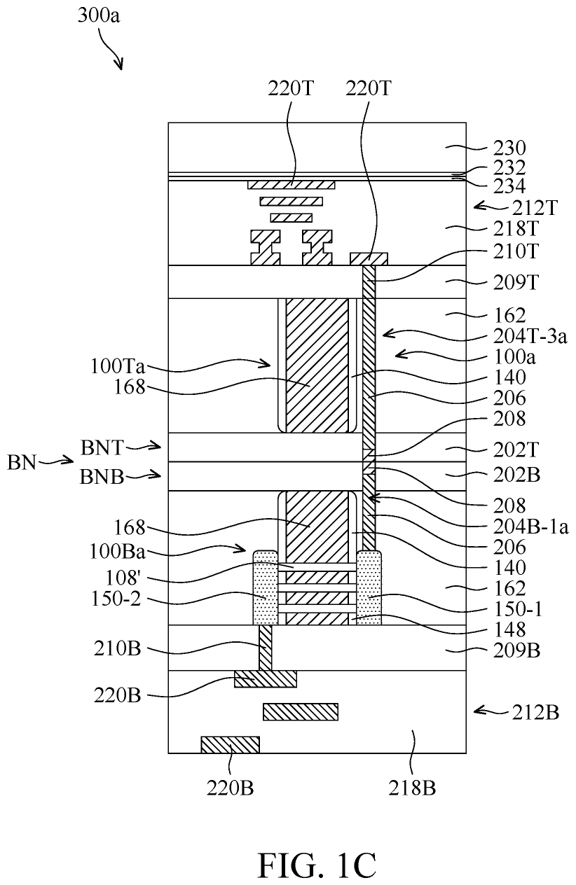

FIG. 1A illustrates a diagrammatic perspective view of a transistor 100a with a bonding structure formed over the transistor 100a in accordance with some embodiments. FIG. 1B illustrates a diagrammatic perspective view of a CFET structure 1000a, including a top transistor 100Ta and a bottom transistor 100Ba, in accordance with some embodiments. FIG. 1C illustrates a cross-section view of a package structure 300a, including the CFET structure 1000a, in accordance with some embodiments. FIGS. 1A to 1C have been simplified for the sake of clarity to better understand the inventive concepts of the present disclosure. Additional features may be included in the transistor 100a, the CFET structure 1000a, and the package structure 300a, and some of the features described below may be replaced, modified, or eliminated. Furthermore, for a better understanding of the structure, the X-Y-Z coordinate reference is provided in the figures.

In some embodiments, the transistor 100a is a nanostructure transistor (e.g. a nanosheet transistor, a nanowire transistor, a multi-bridge channel transistor, a nano-ribbon FET, or a gate all around (GAA) transistor). The transistor 100a may be an n-type transistor or a p-type transistor. In some embodiments, the transistor 100a includes a channel layer 108′, a gate structure 168 wrapping around the channel layer 108′, and source/drain structures 150-1 and 150-2 attached to the channel layer 108′.

The channel layer 108′ may be used as the active region of the transistor 100a and extends between the source/drain structures 150-1 and 150-2 in the X direction. It is noted that although only one channel layer 108′ is shown in FIG. 1A, the transistor 100a may include a number of channel layers 108′ (e.g. two to five) vertically stacked (i.e. in the Z direction). In some embodiments, the channel layer 108′ may include nanostructures, nanosheet structures, or nanowires.

The source/drain structures 150-1 and 150-2 are formed at and attached to the opposite sides of the channel layer 108′ in the X direction, as shown in FIG. 1A in accordance with some embodiments. The gate structure 168 are formed around the channel layer 108′ and between the source/drain structures 150-1 and 150-2 in accordance with some embodiments. In some embodiments, the gate structure 168 is longitudinally oriented (i.e. extending) along Y direction. In some embodiments, gate spacers (e.g. gate spacers 140 shown in FIG. 1C, not shown in FIGS. 1A and 1B for clarity) are formed on the sidewalls of the gate structure 168. In some embodiments, inner spacers (e.g. inner spacers 148 shown in FIG. 1C, not shown in FIGS. 1A and 1B for clarity) are formed to separate the gate structure 168 and the source/drain structures 150-1 and 150-2. In some embodiments, an interlayer dielectric layer (e.g. an interlayer dielectric layer 162 shown in FIG. 1C, not shown in FIGS. 1A and 1B for clarity) is formed over the source/drain structures 150-1 and 150-2.

After the transistor 100a is formed, a bonding structure may be formed over the transistor 100a. In some embodiments, the bonding structure includes a dielectric bonding layer (e.g. dielectric bonding layers 202T and 202B shown in FIG. 1C, not shown in FIGS. 1A and 1B for clarity) and conductive bonding structures 204a. In some embodiments, the conductive bonding structures 204a includes conductive bonding structures 204-1a, 204-2a, and 204-3a formed through the dielectric bonding layer and electrically connected to the transistor 100a. In some embodiments, each of the conductive bonding structures 204-1a, 204-2a, and 204-3a includes a conductive via 206 and a bonding pad 208.

In some embodiments, the conductive bonding structure 204-1a is formed over a top surface the source/drain structure 150-1. In some embodiments, the conductive bonding structure 204-2a is formed over a top surface of the gate structure 168. In some embodiments, the conductive bonding structure 204-3a is laterally spaced apart (e.g. in the Y direction) from the source/drain structure 150-2 but is electrically connected to the source/drain structure 150-2, as shown in FIG. 1A in accordance with some embodiments.

In addition, a backside via 210 is formed at a backside of the source/drain structure 150-2, another backside via 210 is formed at a backside of the conductive bonding structure 204-3a, and a conductive structure 220 of an interconnect structure is formed to laterally connect (e.g. in the Y direction) the conductive bonding structure 204-3 and the source/drain structure 150-2 through the backside vias 210.

Two transistors (e.g. the transistor 100a shown in FIG. 1A) with different conductive types are vertically stacked to form the CFET structure 1000a, as shown in FIG. 1B in accordance with some embodiments. More specifically, one of the transistors 100a may be seen as the top transistor 100Ta and another one of the transistors 100a may be seen as the bottom transistor 100Ba, and the top transistor 100Ta may be flipped over and be attached to the bottom transistor 100Ba. The top transistor 100Ta and the bottom transistor 100Ba may be bonded through the bonding structures. The top transistor 100Ta and the bottom transistor 100Ba can then be seen as the CFET structure 1000a.

As shown in FIG. 1B, a conductive bonding structure 204B-1a formed over the source/drain structure 150-1 of the bottom transistor 100Ba is directly bonded to a conductive bonding structure 204T-3a formed adjacent to and electrically connected to the source/drain structure 150-2 of the top transistor 100Ta in accordance with some embodiments. A conductive bonding structure 204B-2a formed over the gate structure 168 of the bottom transistor 100Ba is directly bonded to a conductive bonding structure 204T-2a formed over the gate structure 168 of the top transistor 100Ta in accordance with some embodiments. A conductive bonding structure 204B-3a formed adjacent to and electrically connected to the source/drain structure 150-2 of the bottom transistor 100Ba is directly bonded to a conductive bonding structure 204T-1a formed over the source/drain structure 150-1 of the top transistor 100Ta in accordance with some embodiments. In some embodiments, the conductive bonding structure 204B-1a, the channel layer 108′ of the bottom transistor 100Ba, the conductive bonding structure 204T-3a, one of the backside vias 210T, and one of the backside vias 210B are substantially aligned with each other in the X direction. In some embodiments, the conductive bonding structures 204B-2a and 204B-3a, the channel layer 108′ of the top transistor 100Ta, the conductive bonding structures 204T-1a and 204T-2a, one of the backside vias 210T, and one of the backside vias 210B are substantially aligned with each other in the X direction. In some embodiments, the channel layer 108′ of the bottom transistor 100Ba is substantially parallel to the channel layer 108′ of the top transistor 100Ta. In some embodiments, the channel layer 108′ of the bottom transistor 100Ba is spaced apart from the channel layer 108′ of the top transistor 100Ta in the Y direction in a top view. In some embodiments, the conductive structure 220T and the conductive structure 220B extend in the Y direction and are substantially parallel to each other.

FIG. 1C illustrates the cross-section view of the package structure 300a in accordance with some embodiments. More specifically, the package structure 300a includes the CFET structure 1000a shown in FIG. 1B, and the cross-sectional view of the package structure 300a is shown in the X direction at the channel layer 108′ of the bottom transistor 100Ba of the CFET structure 1000a in accordance with some embodiments.

As described previously, the CFET structure 1000a is formed by bonding the top transistor 100Ta and the bottom transistor 100Ba through a bonding structure BN in accordance with some embodiments. In some embodiments, the bonding structure BN includes a bonding structure BNB formed over the bottom transistor 100Ba and a bonding structure BNT formed over the top transistor 100Ta. In some embodiments, the bonding structure BNB includes the conductive bonding structures 204B-1a, 204B-2a, 204B-3a formed in a dielectric bonding layer 202B, and the bonding structure BNT includes the conductive bonding structures 204T-1a, 204T-2a, 204T-3a formed in a dielectric bonding layer 202T. Furthermore, the backside vias 210B are formed in a dielectric layer 209B and are electrically connected to the backside of the bottom transistor 100Ba, and the backside vias 210T are formed in a dielectric layer 209T and are electrically connected to the backside of the top transistor 100Ta in accordance with some embodiments. Interconnect structures 212T and 212B with the conductive structure 220T and 220B are formed over and electrically connected to the backside vias 210T and 210B respectively in accordance with some embodiments. In some embodiments, a carrier substrate 230 is bonded to the interconnect structure 212T through adhesive layers 232 and 234. It is noted that some of the backside vias 210B and 210T and some of the conductive structures 220T and 220B have been omitted and are not shown in FIG. 1B and/or FIG. 1C for clarity. The manufacturing the package structure 300a may be described in more details afterwards.

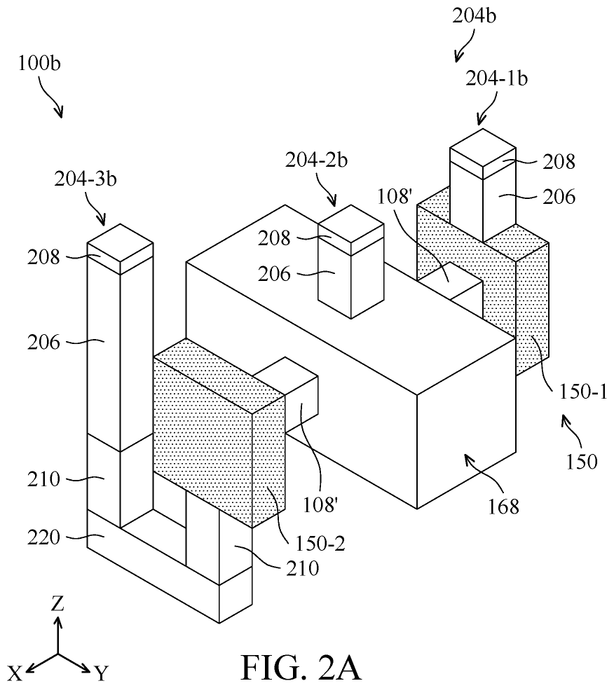

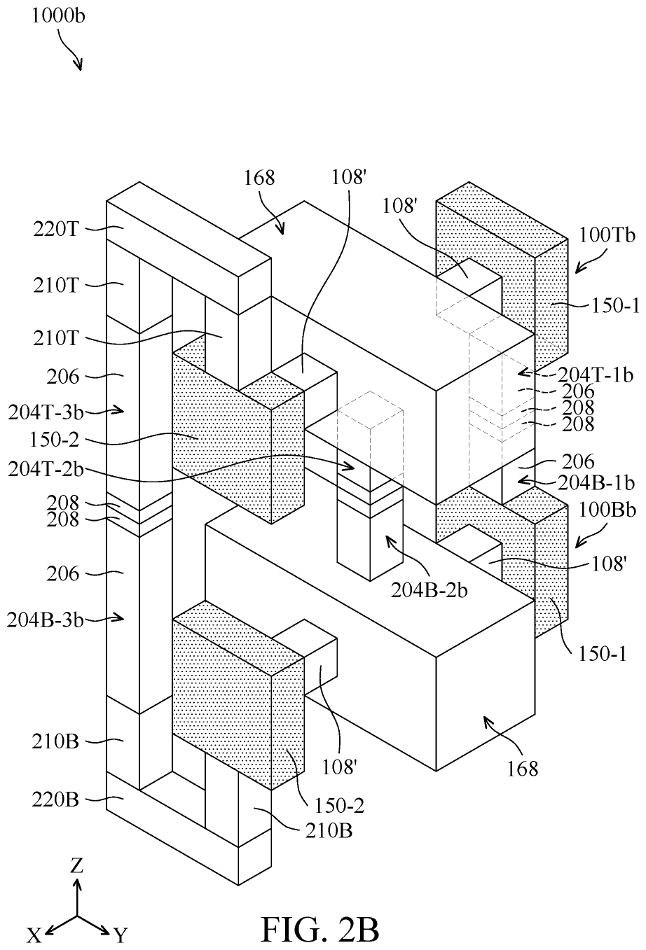

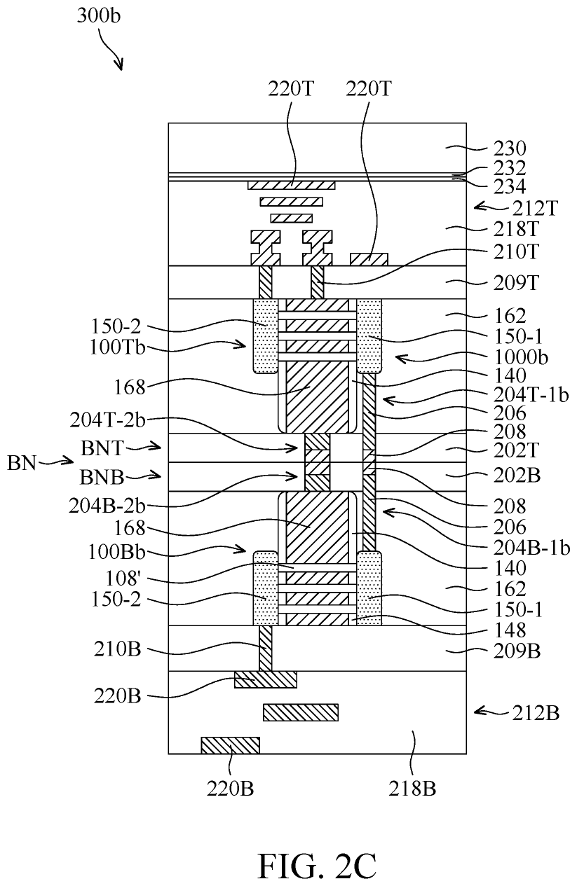

FIG. 2A illustrates a diagrammatic perspective view of a transistor 100b with a bonding structure formed over the transistor 100b in accordance with some embodiments. FIG. 2B illustrates a diagrammatic perspective view of a CFET structure 1000b, including a top transistor 100Tb and a bottom transistor 100Bb, in accordance with some embodiments. FIG. 2C illustrates a cross-section view of a package structure 300b, including the CFET structure 1000b, in accordance with some embodiments. FIGS. 2A to 2C have been simplified for the sake of clarity to better understand the inventive concepts of the present disclosure. Additional features may be included in the transistor 100b, the CFET structure 1000b, and the package structure 300b and some of the features described below may be replaced, modified, or eliminated.

The transistor 100b shown in FIG. 2A is substantially the same as the transistor 100a shown in FIG. 1A, except the location of its conductive bonding structures are different. Similar to that described previously, a bonding structure may be formed over the transistor 100b. In some embodiments, the bonding structure includes a dielectric bonding layer (e.g. dielectric bonding layers 202T and 202B shown in FIG. 2C) and conductive bonding structures 204b formed through the dielectric bonding layer. In some embodiments, the conductive bonding structures 204b includes conductive bonding structures 204-1b, 204-2b, and 204-3b electrically connected to the transistor 100b. In some embodiments, each of the conductive bonding structures 204-1b, 204-2b, and 204-3b includes a conductive via 206 and a bonding pad 208.

In some embodiments, the conductive bonding structure 204-1b is formed over a top surface the source/drain structure 150-1. In some embodiments, the conductive bonding structure 204-2b is formed over a top surface of the gate structure 168. In some embodiments, the conductive bonding structure 204-3b is laterally spaced apart (e.g. in the Y direction) from the source/drain structure 150-2 but is electrically connected to the source/drain structure 150-2. In some embodiments, the conductive bonding structure 204-1b and 204-2b are substantially aligned with the channel layer 108′.

Two transistors (e.g. the transistor 100b shown in FIG. 2A) with different conductive types are vertically stacked to form the CFET structure 1000b, as shown in FIG. 2B in accordance with some embodiments. More specifically, one of the transistors 100b may be seen as the top transistor 100Tb and another one of the transistors 100b may be seen as the bottom transistor 100Bb, and the top transistor 100Tb and the bottom transistor 100Bb can then be seen as the CFET structure 1000b.

As shown in FIG. 2B, a conductive bonding structure 204B-1b formed over the source/drain structure 150-1 of the bottom transistor 100Bb is directly bonded to a conductive bonding structure 204T-1b formed over the source/drain structure 150-1 of the top transistor 100Tb in accordance with some embodiments. A conductive bonding structure 204B-2b formed over the gate structure 168 of the bottom transistor 100Bb is directly bonded to a conductive bonding structure 204T-2b formed over the gate structure 168 of the top transistor 100Tb in accordance with some embodiments. A conductive bonding structure 204B-3b formed adjacent to and electrically connected to the source/drain structure 150-2 of the bottom transistor 100Bb is directly bonded to a conductive bonding structure 204T-3b formed adjacent to and electrically connected to the source/drain structure 150-2 of the top transistor 100Tb in accordance with some embodiments. In some embodiments, the conductive bonding structures 204B-1b and 204B-2b, the channel layer 108′ of the bottom transistor 100Bb, the channel layer 108′ of the top transistor 100Tb, the conductive bonding structures 204T-1b and 204T-2b, one of the backside vias 210T, and one of the backside vias 210B are substantially aligned with each other in the X direction. In some embodiments, the channel layer 108′ of the bottom transistor 100Bb substantially overlaps the channel layer 108′ of the top transistor 100Tb in the Z direction. In some embodiments, the conductive structure 220T and the conductive structure 220B extend in the Y direction and are substantially aligned with each other.

FIG. 2C illustrates the cross-section view of the package structure 300b in accordance with some embodiments. More specifically, the package structure 300b includes the CFET structure 1000b shown in FIG. 2B, and the cross-sectional view of the package structure 300b is shown in the X direction at the channel layer 108′ of the bottom transistor 100Bb of the CFET structure 1000b in accordance with some embodiments. The package structure 300b is substantially the same as the package structure 300a, except the CFET structure 1000a shown in FIG. 1B is replaced by the CFET structure 1000b shown in FIG. 2B, and therefore the details structure of the package structure 300b are not repeated herein.

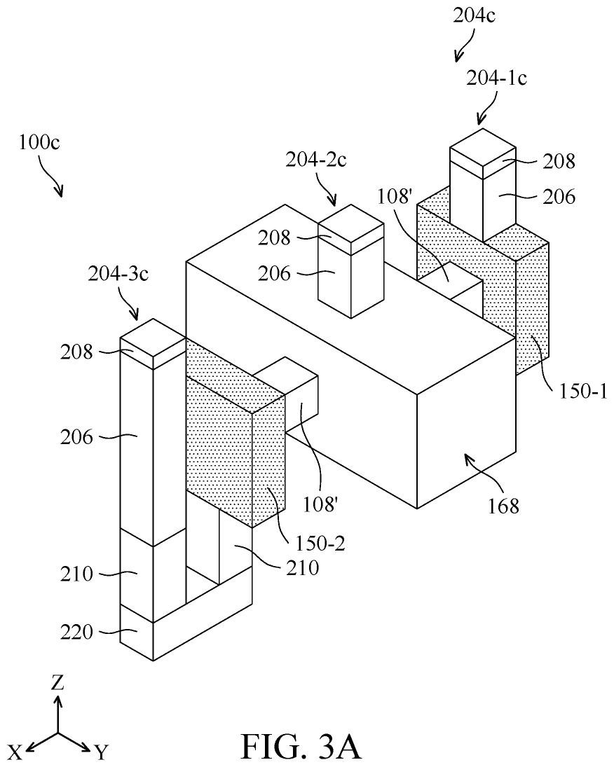

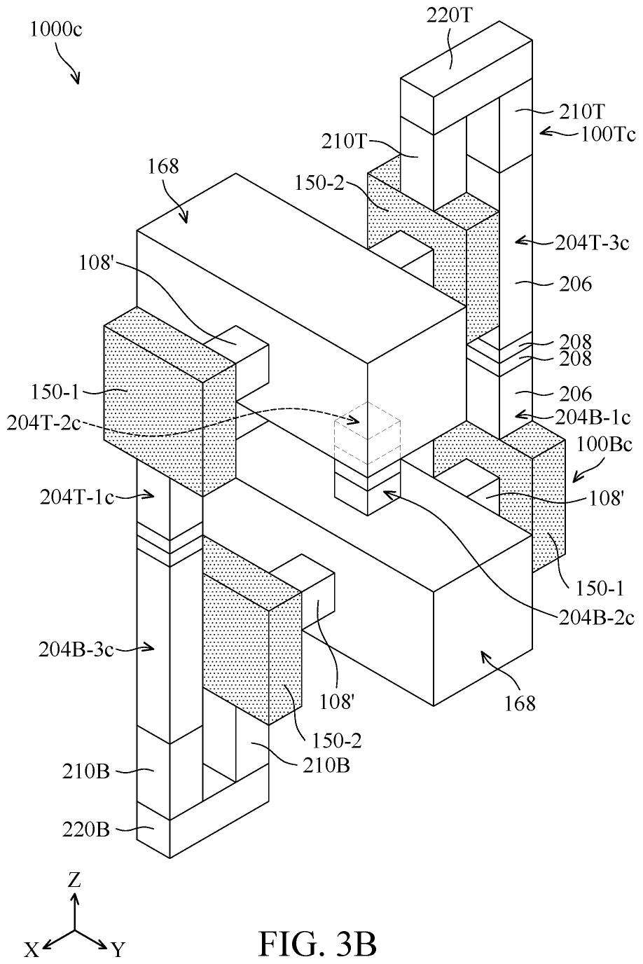

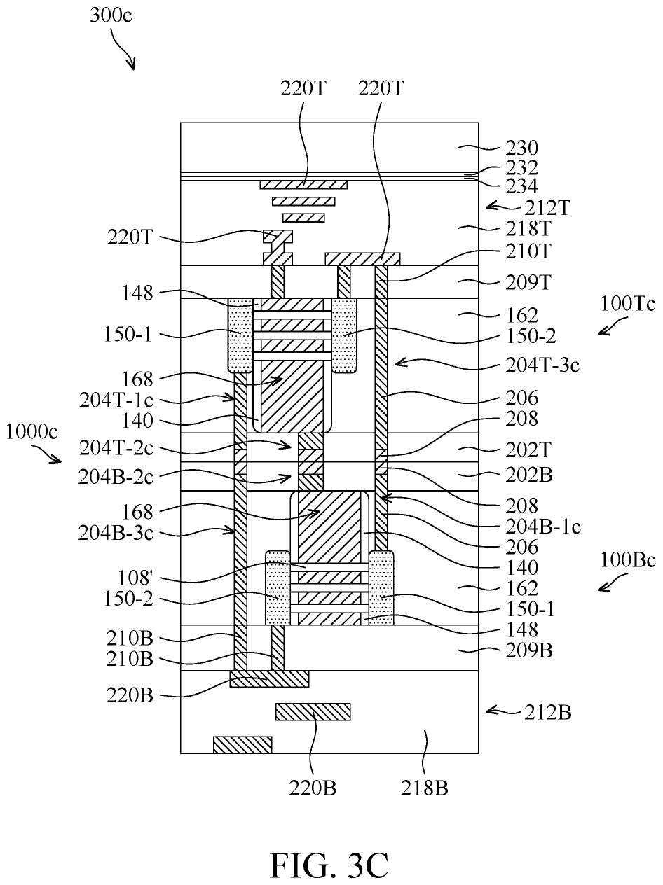

FIG. 3A illustrates a diagrammatic perspective view of a transistor 100c with a bonding structure formed over the transistor 100c in accordance with some embodiments. FIG. 3B illustrates a diagrammatic perspective view of a CFET structure 1000c, including a top transistor 100Tc and a bottom transistor 100Bc, in accordance with some embodiments. FIG. 3C illustrates the cross-section view of a package structure 300c, including the CFET structure 1000c, in accordance with some embodiments. FIGS. 3A to 3C have been simplified for the sake of clarity to better understand the inventive concepts of the present disclosure. Additional features may be included in the transistor 100c, the CFET structure 1000c, and the package structure 300b, and some of the features described below may be replaced, modified, or eliminated.

The transistor 100c shown in FIG. 3A is substantially the same as the transistor 100a shown in FIG. 1A, except the location of its conductive bonding structures are different. Similar to that described previously, a bonding structure may be formed over the transistor 100c. In some embodiments, the bonding structure includes a dielectric bonding layer (e.g. dielectric bonding layers 202T and 202B shown in FIG. 3C) and conductive bonding structures 204c formed through the dielectric bonding layer. In some embodiments, the conductive bonding structures 204c includes conductive bonding structures 204-1c, 204-2c, and 204-3c electrically connected to the transistor 100c. In some embodiments, each of the conductive bonding structures 204-1c, 204-2c, and 204-3c includes a conductive via 206 and a bonding pad 208.

In some embodiments, the conductive bonding structure 204-1c is formed over a top surface the source/drain structure 150-1. In some embodiments, the conductive bonding structure 204-2c is formed over a top surface of the gate structure 168. In some embodiments, the conductive bonding structure 204-3c is laterally spaced apart (e.g. in the X direction) from the source/drain structure 150-2 but is electrically connected to the source/drain structure 150-2. In some embodiments, the conductive bonding structure 204-1c, 204-2c, and 204-3c are substantially aligned with the channel layer 108′.

Two transistors (e.g. the transistor 100c shown in FIG. 3A) with different conductive types are vertically stacked to form the CFET structure 1000c, as shown in FIG. 3B in accordance with some embodiments. More specifically, one of the transistors 100c may be seen as the top transistor 100Tc and another one of the transistors 100c may be seen as a bottom transistor 100Bc, and the top transistor 100Tc and the bottom transistor 100Bc can then be seen as the CFET structure 1000c.

As shown in FIG. 3B, a conductive bonding structure 204B-1c formed over the source/drain structure 150-1 of the bottom transistor 100Bc is directly bonded to a conductive bonding structure 204T-3c formed adjacent to and electrically connected to the source/drain structure 150-2 of the top transistor 100Tc in accordance with some embodiments. A conductive bonding structure 204B-2c formed over the gate structure 168 of the bottom transistor 100Bb is directly bonded to a conductive bonding structure 204T-2c formed over the gate structure 168 of the top transistor 100Tc in accordance with some embodiments. A conductive bonding structure 204B-3c formed adjacent to and electrically connected to the source/drain structure 150-2 of the bottom transistor 100Bb is directly bonded to a conductive bonding structure 204T-1c formed over the source/drain structure 150-1 of the top transistor 100Tc in accordance with some embodiments. In some embodiments, the conductive bonding structures 204B-1c, 204B-2c, and 204B-3c, the channel layer 108′ of the bottom transistor 100Bc, the channel layer 108′ of the top transistor 100Tc, the conductive bonding structures 204T-1c, 204T-2c, and 204T-3c, the backside vias 210T, and the backside vias 210B are substantially aligned with each other in the X direction. In some embodiments, the channel layer 108′ of the bottom transistor 100Bc substantially overlaps the channel layer 108′ of the top transistor 100Tc in the Z direction. In some embodiments, the conductive structure 220T and the conductive structure 220B extend in the Y direction and are substantially aligned with each other.

FIG. 3C illustrates the cross-section view of the package structure 300c in accordance with some embodiments. More specifically, the package structure 300c includes the CFET structure 1000c shown in FIG. 3B, and the cross-sectional view of the package structure 300c is shown in the X direction at the channel layer 108′ of the bottom transistor 100Bc of the CFET structure 1000c in accordance with some embodiments. The package structure 300c is substantially the same as the package structure 300a, except the CFET structure 1000a shown in FIG. 1B is replaced by the CFET structure 1000c shown in FIG. 3B, and therefore the details structure of the package structure 300c are not repeated herein.

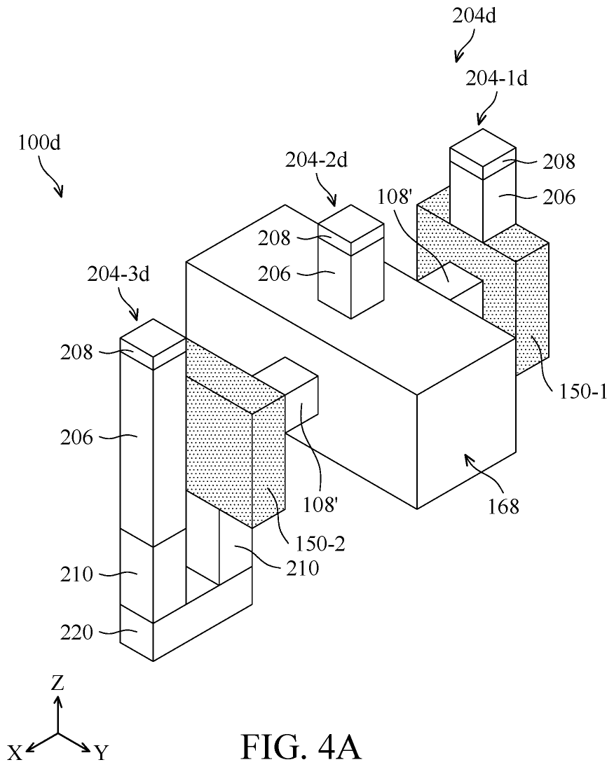

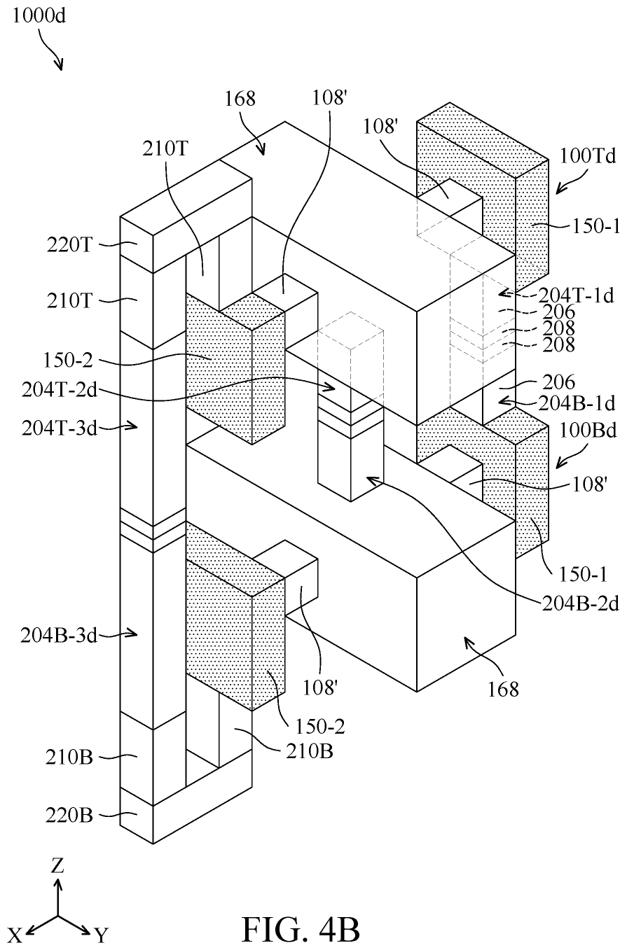

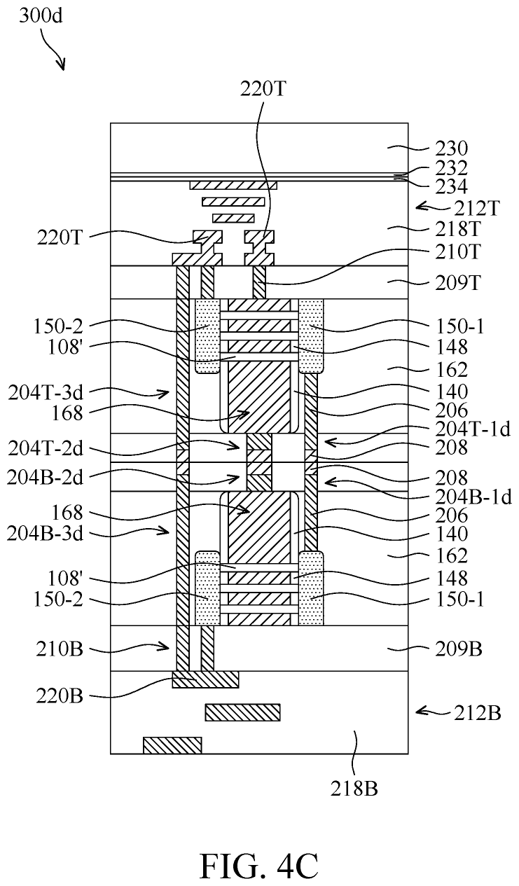

FIG. 4A illustrates a diagrammatic perspective view of a transistor 100d with a bonding structure formed over the transistor 100d in accordance with some embodiments. FIG. 4B illustrates a diagrammatic perspective view of a CFET structure 1000d, including a top transistor 100Td and a bottom transistor 100Bd, in accordance with some embodiments. FIG. 4C illustrates a cross-section view of a package structure 300d, including the CFET structure 1000d, in accordance with some embodiments. FIGS. 4A to 4C have been simplified for the sake of clarity to better understand the inventive concepts of the present disclosure. Additional features may be included in the transistor 100d, the CFET structure 1000d, and the package structure 300d, and some of the features described below may be replaced, modified, or eliminated.

The transistor 100d shown in FIG. 4A is substantially the same as the transistor 100a shown in FIG. 1A, except the location of its conductive bonding structures are different. Similar to that described previously, a bonding structure may be formed over the transistor 100d. In some embodiments, the bonding structure includes a dielectric bonding layer (e.g. dielectric bonding layers 202T and 202B shown in FIG. 4C) and conductive bonding structures 204d. In some embodiments, the conductive bonding structures 204d includes conductive bonding structures 204-1d, 204-2d, and 204-3d electrically connected to the transistor 100d. In some embodiments, each of the conductive bonding structures 204-1d, 204-2d, and 204-3d includes a conductive via 206 and a bonding pad 208.

In some embodiments, the conductive bonding structure 204-1d is formed over a top surface the source/drain structure 150-1. In some embodiments, the conductive bonding structure 204-2d is formed over a top surface of the gate structure 168. In some embodiments, the conductive bonding structure 204-3d is laterally spaced apart (e.g. in the X direction) from the source/drain structure 150-2 but is electrically connected to the source/drain structure 150-2. In some embodiments, the conductive bonding structure 204-1d, 204-2d, and 204-3d are substantially aligned with the channel layer 108′.

Two transistors (e.g. the transistor 100d shown in FIG. 4A) with different conductive types are vertically stacked to form the CFET structure 1000d, as shown in FIG. 4B in accordance with some embodiments. More specifically, one of the transistors 100d may be seen as the top transistor 100Td and another one of the transistors 100d may be seen as the bottom transistor 100Bd, and the top transistor 100Td and the bottom transistor 100Bd can then be seen as the CFET structure 1000d.

As shown in FIG. 4B, a conductive bonding structure 204B-1d formed over the source/drain structure 150-1 of the bottom transistor 100Bd is directly bonded to a conductive bonding structure 204T-1d formed over the source/drain structure 150-1 of the top transistor 100Td in accordance with some embodiments. A conductive bonding structure 204B-2d formed over the gate structure 168 of the bottom transistor 100Bd is directly bonded to a conductive bonding structure 204T-2d formed over the gate structure 168 of the top transistor 100Td in accordance with some embodiments. A conductive bonding structure 204B-3d formed adjacent to and electrically connected to the source/drain structure 150-2 of the bottom transistor 100Bd is directly bonded to a conductive bonding structure 204T-3d formed adjacent to and electrically connected to the source/drain structure 150-2 of the top transistor 100Td in accordance with some embodiments. In some embodiments, the conductive bonding structures 204B-1d, 204B-2d, and 204B-3d, the channel layer 108′ of the bottom transistor 100Bd, the channel layer 108′ of the top transistor 100Td, the conductive bonding structures 204T-1d, 204T-2d, and 204T-3d, the backside vias 210T, and the backside vias 210B are substantially aligned with each other in the X direction. In some embodiments, the channel layer 108′ of the bottom transistor 100Bd substantially overlaps the channel layer 108′ of the top transistor 100Td in the Z direction. In some embodiments, the conductive structure 220T and the conductive structure 220B extend in the X direction and are substantially aligned with each other in the Z direction.

FIG. 4C illustrates the cross-section view of the package structure 300d in accordance with some embodiments. More specifically, the package structure 300d includes the CFET structure 1000d shown in FIG. 4B, and the cross-sectional view of the package structure 300d is shown in the X direction at the channel layer 108′ of the bottom transistor 100Bd of the CFET structure 1000d in accordance with some embodiments. The package structure 300d is substantially the same as the package structure 300a, except the CFET structure 1000a shown in FIG. 1B is replaced by the CFET structure 1000d shown in FIG. 4B, and therefore the details structure of the package structure 300d are not repeated herein.

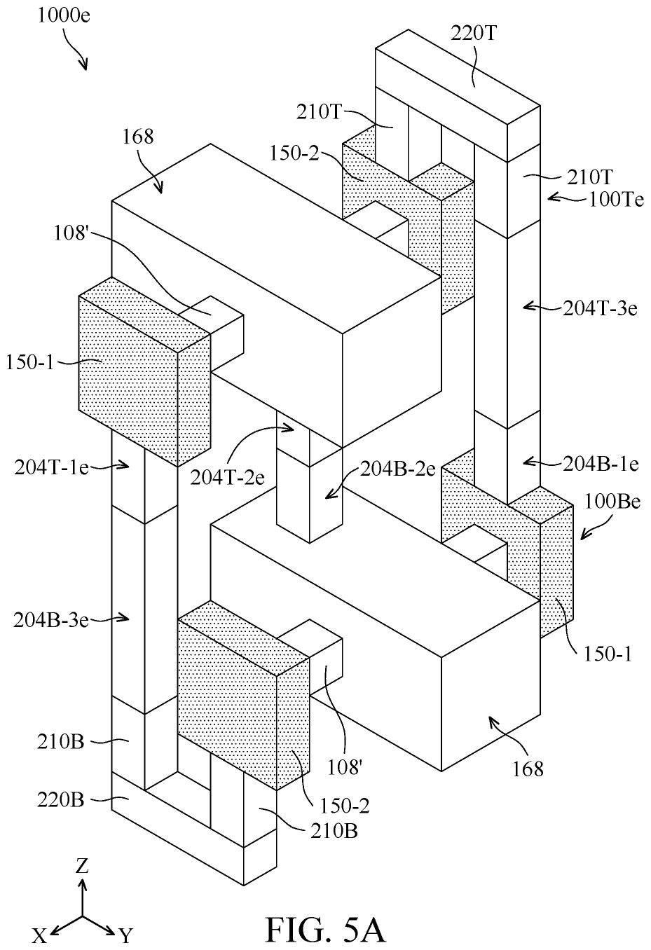

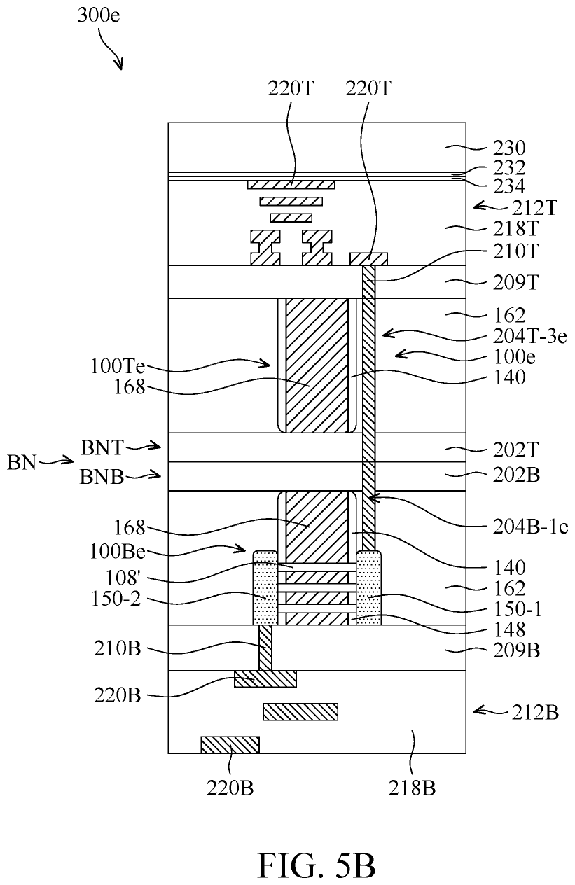

FIG. 5A illustrates a diagrammatic perspective view of a CFET structure 1000e, including a top transistor 100Te and a bottom transistor 100Be, in accordance with some embodiments. The CFET structure 1000e is substantially the same as the CFET structure 1000a shown in FIG. 1B, except each of conductive bonding structures 204B-1, 204B-2e, 204B-3e, 204T-1, 204T-2e, and 204T-3e is made of a single conductive material. That is, instead of forming the conductive bonding structures with a conductive via 206 and a bonding pad 208 shown in FIG. 1B, each of the conductive bonding structures 204B-1, 204B-2e, 204B-3e, 204T-1, 204T-2e, and 204T-3e is made of a single conductive bonding material, such as Co, W, or the like.

FIG. 5B illustrates a cross-section view of a package structure 300e in accordance with some embodiments. More specifically, the package structure 300e includes the CFET structure 1000e shown in FIG. 5A, and the cross-sectional view of the package structure 300e is shown in the X direction at the channel layer 108′ of the bottom transistor 100Be of the CFET structure 1000e in accordance with some embodiments. The package structure 300e is substantially the same as the package structure 300a, except the CFET structure 1000a shown in FIG. 1B is replaced by the CFET structure 1000e shown in FIG. 5A, and therefore the details structure of the package structure 300e are not repeated herein.

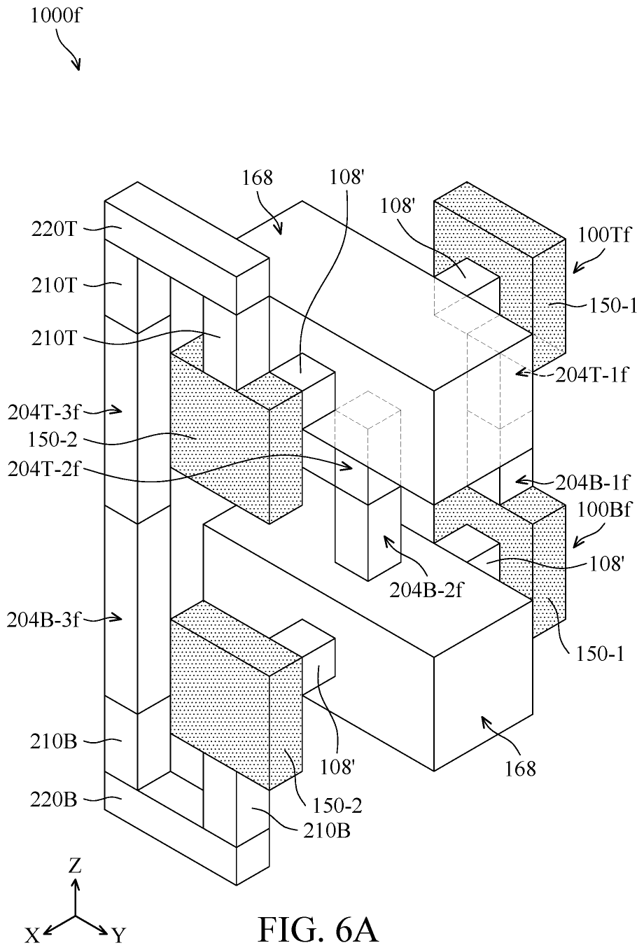

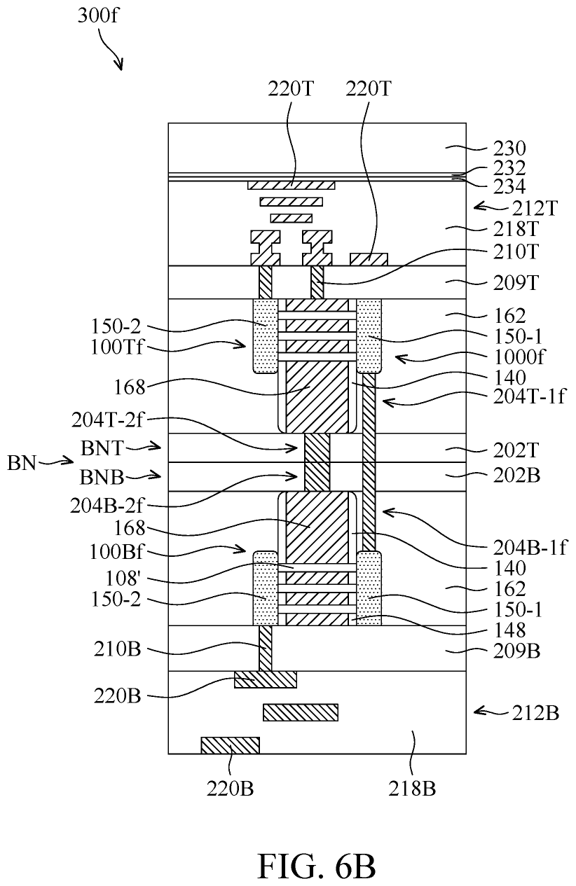

FIG. 6A illustrates a diagrammatic perspective view of a CFET structure 1000f, including a top transistor 100Tf and a bottom transistor 100Bf, in accordance with some embodiments. The CFET structure 1000f is substantially the same as the CFET structure 1000b shown in FIG. 2B, except each of conductive bonding structures 204B-1f, 204B-2f, 204B-3f, 204T-1f, 204T-2f, and 204T-3f is made of a single conductive material. That is, instead of forming the conductive bonding structures with a conductive via 206 and a bonding pad 208 shown in FIG. 2B, each of the conductive bonding structures 204B-1f, 204B-2f, 204B-3f, 204T-1f, 204T-2f, and 204T-3f is made of a single conductive bonding material, such as Co, W, or the like.

FIG. 6B illustrates the cross-section view of a package structure 300f in accordance with some embodiments. More specifically, the package structure 300f includes the CFET structure 1000f shown in FIG. 6A, and the cross-sectional view of the package structure 300f is shown in the X direction at the channel layer 108′ of the bottom transistor 100Bf of the CFET structure 1000f in accordance with some embodiments. The package structure 300f is substantially the same as the package structure 300b, except the CFET structure 1000b shown in FIG. 2B is replaced by the CFET structure 1000f shown in FIG. 6A, and therefore the details structure of the package structure 300f are not repeated herein.

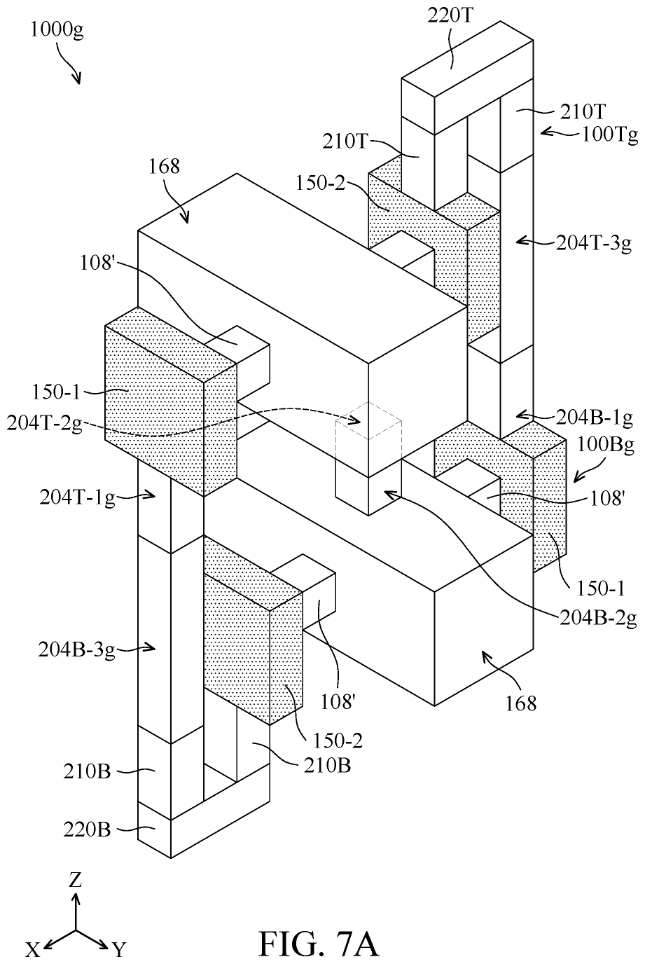

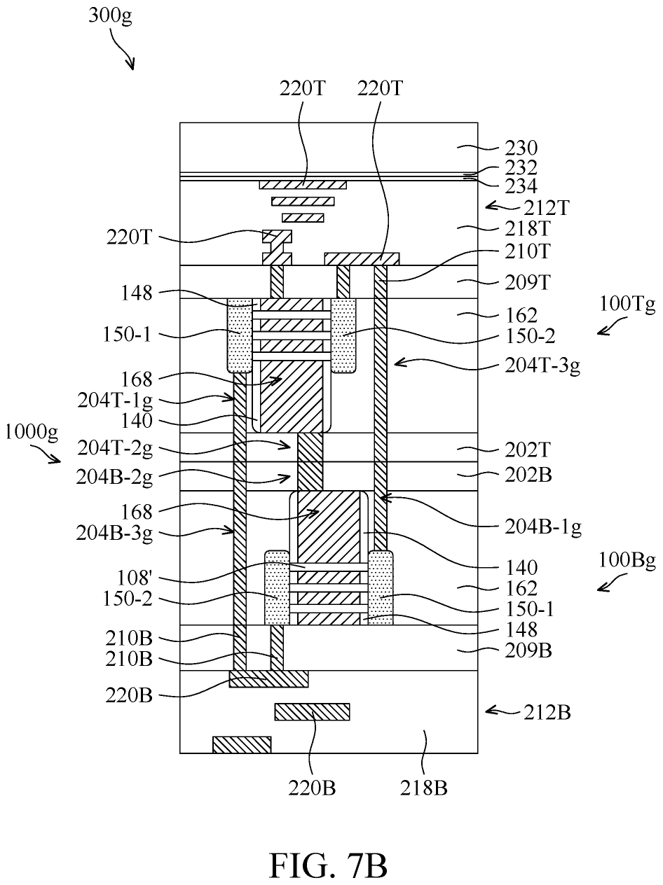

FIG. 7A illustrates a diagrammatic perspective view of a CFET structure 1000g, including a top transistor 100Tg and a bottom transistor 100Bg, in accordance with some embodiments. The CFET structure 1000g is substantially the same as the CFET structure 1000c shown in FIG. 3B, except each of conductive bonding structures 204B-1g, 204B-2g, 204B-3g, 204T-1g, 204T-2g, and 204T-3g is made of a single conductive material. That is, instead of forming the conductive bonding structures with a conductive via 206 and a bonding pad 208 shown in FIG. 3B, each of the conductive bonding structures 204B-1g, 204B-2g, 204B-3g, 204T-1g, 204T-2g, and 204T-3g is made of a single conductive bonding material, such as Co, W, or the like.

FIG. 7B illustrates a cross-section view of a package structure 300g in accordance with some embodiments. More specifically, the package structure 300g includes the CFET structure 1000g shown in FIG. 7A, and the cross-sectional view of the package structure 300g is shown in the X direction at the channel layer 108′ of the bottom transistor 100Bg of the CFET structure 1000g in accordance with some embodiments. The package structure 300g is substantially the same as the package structure 300c, except the CFET structure 1000c shown in FIG. 3B is replaced by the CFET structure 1000g shown in FIG. 7A, and therefore the details structure of the package structure 300g are not repeated herein.

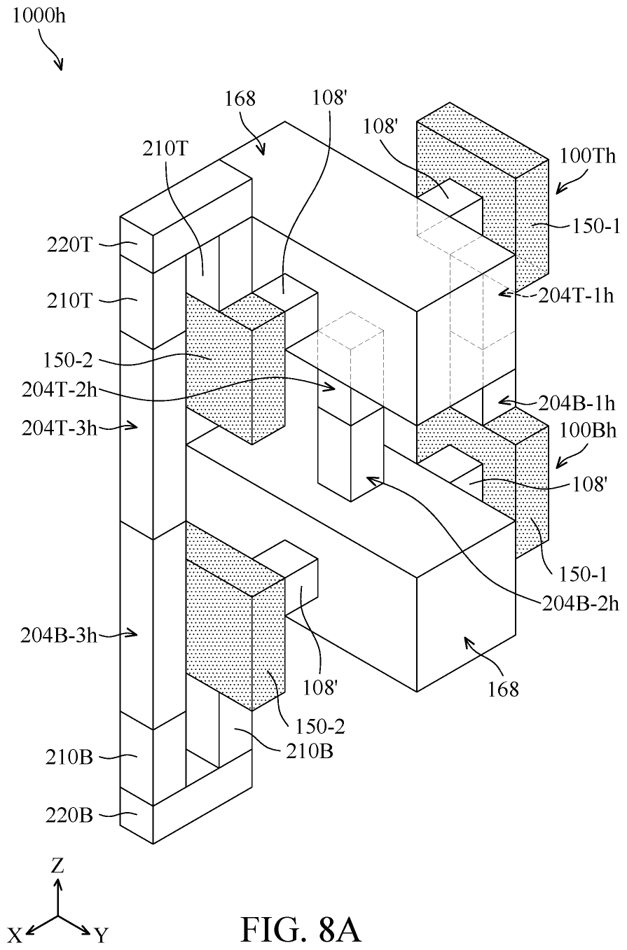

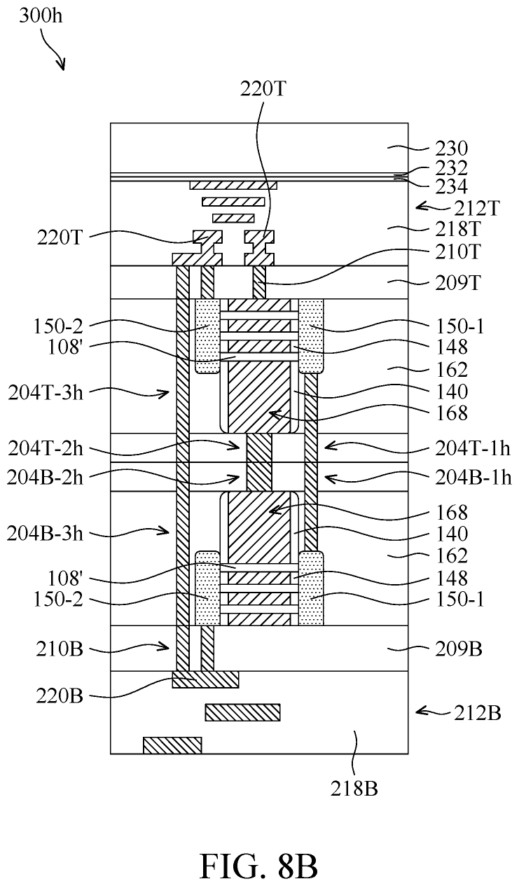

FIG. 8A illustrates a diagrammatic perspective view of a CFET structure 1000h, including a top transistor 100Th and a bottom transistor 100B, in accordance with some embodiments. The CFET structure 1000h is substantially the same as the CFET structure 1000d shown in FIG. 4B, except each of conductive bonding structures 204B-1h, 204B-2h, 204B-3h, 204T-1h, 204T-2h, and 204T-3h is made of a single conductive material. That is, instead of forming the conductive bonding structures with a conductive via 206 and a bonding pad 208 shown in FIG. 4B, each of the conductive bonding structures 204B-1h, 204B-2h, 204B-3h, 204T-1h, 204T-2h, and 204T-3h is made of a single conductive bonding material, such as Co, W, or the like.

FIG. 8B illustrates a cross-section view of a package structure 300h in accordance with some embodiments. More specifically, the package structure 300h includes the CFET structure 1000h shown in FIG. 8A, and the cross-sectional view of the package structure 300h is shown in the X direction at the channel layer 108′ of the bottom transistor 100Bh of the CFET structure 1000h in accordance with some embodiments. The package structure 300h is substantially the same as the package structure 300d, except the CFET structure 1000d shown in FIG. 4B is replaced by the CFET structure 1000h shown in FIG. 8A, and therefore the details structure of the package structure 300h are not repeated herein.

The materials and method for manufacturing the CFET structure 1000b and the package structure 300b are described below as an example. The materials and method for manufacturing the CFET structures 1000a, 1000c, 1000d, 1000e, 1000f, 1000g, and 1000h and the package structure 300a, 300c, 300d, 300e, 300f, 300g, and 300h may be similar to those for manufacturing the CFET structure 1000b and the package structure 300b described below and are not repeated herein.

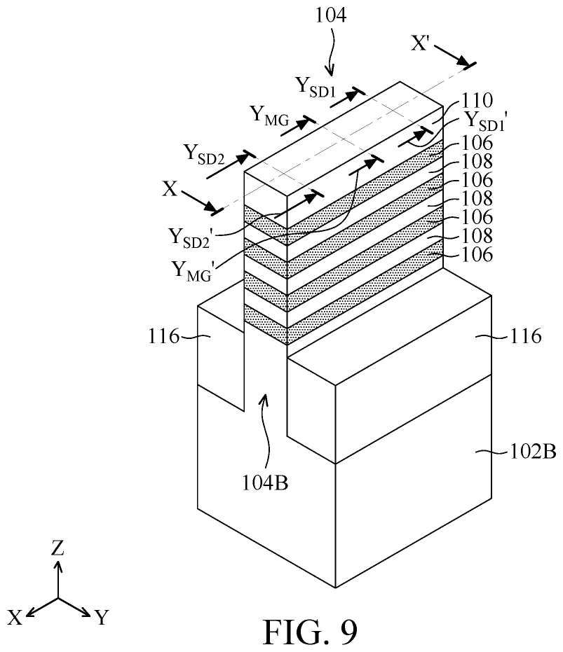

FIG. 9 illustrates a diagrammatic perspective view of an intermediate stage of manufacturing the CFET structure 1000b in accordance with some embodiments. FIGS. 10A-1 to 10H-1, 10A-2 to 10H-2, 10A-3 to 10H-3, and 10A-4 to 10H-4 illustrate the cross-sectional views of intermediate stages of manufacturing the CFET structure 1000b shown along line Y_{SD1}-Y_{SD1′} (i.e. in the Y direction), Y_{MG}-Y_{MG′} (i.e. in the Y direction), Y_{SD2}-Y_{SD2′} (i.e. in the Y direction), and X-X′ (i.e. in the X direction) in FIG. 9, respectively, in accordance with some embodiments. More specifically, FIGS. 10A-1, 10A-2, 10A-3, and 10A-4 illustrate the cross-sectional views of the intermediate stage of manufacturing the CFET structure 1000b shown in FIG. 9, and FIGS. 10B-1 to 10H-1, 10B-2 to 10H-2, 10B-3 to 10H-3, and 10B-4 to 10H-4 illustrate the cross-sectional views of the intermediate stages of manufacturing the CFET structure 1000b afterwards in accordance with some embodiments.

First, a substrate 102B is formed and a semiconductor stack, including first semiconductor material layers 106 and second semiconductor material layers 108, is formed over the substrate 102B, as shown in FIGS. 9, 10A-1, 10A-2, 10A-3, and 10A-4 in accordance with some embodiments. The substrate 102B may be a semiconductor wafer such as a silicon wafer. Alternatively or additionally, the substrate 102B may include elementary semiconductor materials, compound semiconductor materials, and/or alloy semiconductor materials. Elementary semiconductor materials may include, but are not limited to, crystal silicon, polycrystalline silicon, amorphous silicon, germanium, and/or diamond. Compound semiconductor materials may include, but are not limited to, silicon carbide, gallium arsenic, gallium phosphide, indium phosphide, indium arsenide, and/or indium antimonide. Alloy semiconductor materials may include, but are not limited to, SiGe, GaAsP, AlInAs, AlGaAs, GaInAs, GaInP, and/or GaInAsP.

In some embodiments, the first semiconductor material layers 106 and the second semiconductor material layers 108 are alternately stacked over the substrate 102B to form the semiconductor stack. In some embodiment, the first semiconductor material layers 106 and the second semiconductor material layers 108 are made of different semiconductor materials. In some embodiments, the first semiconductor material layers 106 are made of SiGe, and the second semiconductor material layers 108 are made of silicon. It should be noted that although four first semiconductor material layers 106 and three second semiconductor material layers 108 are shown in FIG. 9, the semiconductor stack may include less or more of the first semiconductor material layers 106 and the second semiconductor material layers 108 alternately stacked. For example, the semiconductor stack may include two to five of the first semiconductor material layers 106 and two to five of the second semiconductor material layers 108.

After the first semiconductor material layers 106 and the second semiconductor material layers 108 are formed as the semiconductor stack over the substrate 102B, the semiconductor stack is patterned to form a fin structure 104, as shown in FIGS. 9, 10A-1, 10A-2, 10A-3, and 10A-4 in accordance with some embodiments. The fin structure 104 may extend lengthwise in the X direction. In some embodiments, the patterning process includes forming a mask structure 110 over the semiconductor material stack and etching the semiconductor material stack and the underlying substrate 102B through the mask structure 110. In some embodiments, the mask structure 110 is a multilayer structure including a pad oxide layer and a nitride layer formed over the pad oxide layer. In some embodiments, the fin structure 104 includes base fin structure 104B and the semiconductor stack formed over the base fin structure 104B.

After the fin structure 104 is formed, an isolation structure 116 is formed around the fin structure 104, as shown in FIGS. 9, 10A-1, 10A-2, 10A-3, and 10A-4 in accordance with some embodiments. The isolation structure 116 is configured to electrically isolate the active regions (e.g. the fin structure 104) of the semiconductor structure and is also referred to as shallow trench isolation (STI) feature in accordance with some embodiments.

More specifically, an insulating layer may be formed around and covering the fin structure 104, and the insulating layer may be recessed to form the isolation structure 116 with the fin structure 104 protruding from the top surface of the isolation structure 116. In some embodiments, the insulating layer is made of silicon oxide, silicon nitride, silicon oxynitride (SiON), another suitable insulating material, or a combination thereof. In addition, liner layers (not shown) may be formed before forming the insulating layer, and the liner layers may also be recessed with the insulating layer to form the isolation structure 116. In some embodiments, the liner layers include multiple dielectric material layers.

Afterwards, a dummy gate structure 130 is formed across the fin structure 104, and gate spacers 140 and fin spacers 142 are formed on sidewalls of the dummy gate structure 130 and the fin structure 104, as shown in FIGS. 10B-1, 10B-2, 10B-3, and 10B-4 in accordance with some embodiments. The dummy gate structure 130 may be used to define the channel regions of the resulting transistor structure.

In some embodiments, the dummy gate structure 130 includes a dummy gate dielectric layer 132 and a dummy gate electrode layer 134. In some embodiments, the dummy gate dielectric layer 132 is made of one or more dielectric materials, such as silicon oxide, silicon nitride, silicon oxynitride (SiON), HfO₂, HfZrO, HfSiO, HfTiO, HfAlO, or a combination thereof. In some embodiments, the dummy gate electrode layer 134 is made of conductive material includes polycrystalline-silicon (poly-Si), poly-crystalline silicon-germanium (poly-SiGe), or a combination thereof. In some embodiments, a hard mask layer 136 is formed over the dummy gate electrode layer 134. In some embodiments, the hard mask layer 136 includes multiple layers, such as an oxide layer and a nitride layer. In some embodiments, the oxide layer is silicon oxide, and the nitride layer is silicon nitride.

After the dummy gate structure 130 is formed, a spacer layer may be formed to cover the top surfaces and the sidewalls of the dummy gate structure 130 and the fin structure 104, and an etching process may be performed to form the gate spacers 140, the fin spacers 142, and source/drain recesses 144 in the fin structure 104, as shown in FIGS. 10B-1, 10B-2, 10B-3, and 10B-4 in accordance with some embodiments. The gate spacers 140 may be configured to separate source/drain structures (formed afterwards) from the dummy gate structure 130, and the fin spacers 142 may be configured to confine the growth of the source/drain structures formed therein.

In some embodiments, the spacer layer is made one or more dielectric materials. The dielectric materials may include silicon oxide (SiO₂), silicon nitride (SiN), silicon carbide (SiC), silicon oxynitride (SiON), silicon carbon nitride (SiCN), silicon oxide carbonitride (SiOCN), and/or a combination thereof. After the spacer layer is formed, the spacer layer is etched to form the gate spacers 140 on opposite sidewalls of the dummy gate structure 130 and to form the fin spacers 142 covering the sidewalls of the fin structure 104 in accordance with some embodiments. In addition, the portions of the fin structure 104 not covered by the dummy gate structure 130 and the gate spacers 140 are etched to form the source/drain recesses 144 during the etching process in accordance with some embodiments. The etching process may be an anisotropic etching process, such as dry plasma etching, and the dummy gate structure 130 and the gate spacers 140 may be used as etching masks during the etching process. In some embodiments, the isolation structure 116 is also slightly etched during the etching process.

After the source/drain recesses 144 are formed, the first semiconductor material layers 106 exposed by the source/drain recesses 144 are laterally recessed to form notches, and inner spacers 148 are formed in the notches, as shown in FIGS. 10C-1, 10C-2, 10C-3, and 10C-4 in accordance with some embodiments. In some embodiments, an etching process is performed to laterally recess the first semiconductor material layers 106 of the fin structure 104 from the source/drain recesses 144. In some embodiments, during the etching process, the first semiconductor material layers 106 have a greater etching rate (or etching amount) than the second semiconductor material layers 108, thereby forming notches between the adjacent second semiconductor material layers 108.

Next, the inner spacers 148 are formed in the notches between the second semiconductor material layers 108 in accordance with some embodiments. The inner spacers 148 may be configured to separate the source/drain structures and the gate structure formed in subsequent manufacturing processes. In some embodiments, the inner spacers 148 are made of a dielectric material, such as silicon oxide (SiO₂), silicon nitride (SiN), silicon carbide (SiC), silicon oxynitride (SiON), silicon carbon nitride (SiCN), silicon oxide carbonitride (SiOCN), or a combination thereof.

After the inner spacers 148 are formed, the source/drain structures 150-1 and 150-2 are formed in the source/drain recesses 144, and a contact etch stop layer 160 and an interlayer dielectric layer 162 are formed over the source/drain structures 150-1 and 150-2, as shown in FIGS. 10C-1, 10C-2, 10C-3, and 10C-4 in accordance with some embodiments. The source/drain structures described herein may refer to a source or a drain, individually or collectively dependent upon the context.

In some embodiments, the source/drain structures 150-1 and 150-2 are formed using epitaxial growth processes, such as MBE, MOCVD, VPE, other applicable epitaxial growth process, or a combination thereof. In some embodiments, the source/drain structures 150-1 and 150-2 are made of any applicable material, such as Ge, Si, GaAs, AlGaAs, SiGe, GaAsP, SiP, SiC, SiCP, or a combination thereof. In some embodiments, the source/drain structures 150-1 and 150-2 are in-situ doped during the epitaxial growth process. In some embodiments, the source/drain structures 150-1 and 150-2 are doped in one or more implantation processes after the epitaxial growth process.

After the source/drain structures 150-1 and 150-2 are formed, the contact etch stop layer (CESL) 160 is conformally formed to cover the source/drain structures 150-1 and 150-2, and the interlayer dielectric (ILD) layer 162 is formed over the contact etch stop layers 160 in accordance with some embodiments. In some embodiments, the contact etch stop layer 160 is made of a dielectric materials, such as silicon nitride, silicon oxide, silicon oxynitride, another suitable dielectric material, or a combination thereof. The dielectric material of the contact etch stop layers 160 may be conformally deposited over the semiconductor structure by performing CVD, ALD, other application methods, or a combination thereof.

The interlayer dielectric layer 162 may include multilayers made of multiple dielectric materials, such as silicon oxide, silicon nitride, silicon oxynitride, phosphosilicate glass (PSG), borophosphosilicate glass (BPSG), or other applicable low-k dielectric materials. The interlayer dielectric layer 162 may be formed by chemical vapor deposition (CVD), physical vapor deposition, (PVD), atomic layer deposition (ALD), or other applicable processes.

After the contact etch stop layer 160 and the interlayer dielectric layer 162 are deposited, a planarization process such as CMP or an etch-back process is performed until the dummy gate electrode layer 134 is exposed in accordance with some embodiments. Next, the dummy gate structure 130 and the first semiconductor material layers 106 are removed to form a gate trench, and a gate structure 168 is formed in the gate trench, as shown in FIGS. 10D-1, 10D-2, 10D-3, and 10D-4 in accordance with some embodiments.

More specifically, the dummy gate structure 130 and the first semiconductor material layers 106 are removed to form channel layers (e.g. nanostructures) 108′ with the second semiconductor material layers 108 of the fin structure 104 in accordance with some embodiments. As shown in FIGS. 10D-2 and 10D-4, the channel layers 108′ are vertically suspended over the substrate 102B and spaced apart from each other in the Z direction in accordance with some embodiments. In addition, the channel layers 108′ laterally extend between and interposing the source/drain structures 150-1 and 150-2 in the X direction in accordance with some embodiments.

After the channel layers 108′ are formed, an interfacial layer 170, a gate dielectric layer 172, and a gate stack 174 are formed to wrap the channel layers 108′ as the gate structure 168, as shown in FIGS. 10D-1, 10D-2, 10D-3, and 10D-4 in accordance with some embodiments. The interfacial layer 170 may be used to improve the interfaces between the channel layers 108′ and dielectric layers formed afterwards. In addition, the interfacial layer 170 may be able to help suppressing the mobility degradation of charge carries in the channel layers 108′ that serve as channel regions of the transistors. In some embodiments, the interfacial layer 170 is an oxide layer formed by performing a thermal process. In some embodiments, the interfacial layer 170 has a thickness in a range from about 0.5 nm to about 1.5 nm.

After the interfacial layer 170 is formed, the gate dielectric layer 172 is conformally formed in the gate trench in accordance with some embodiments. In some embodiments, the gate dielectric layer 172 covers the interfacial layer 170 and wraps around the channel layers 108′. In some embodiments, the gate dielectric layer 172 is made of one or more layers of dielectric materials, such as HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other applicable high-k dielectric materials, or a combination thereof. In some embodiments, the gate dielectric layer 172 is formed using CVD, ALD, other applicable methods, or a combination thereof.

Next, the gate stack 174 is formed over the gate dielectric layers 172, and the bottom transistor 100Bb of the CFET structure 1000 is formed, as shown in 10D-1, 10D-2, 10D-3, and 10D-4 in accordance with some embodiments. In some embodiments, the gate stack 174 is made of one or more layers of conductive material, such as aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, another suitable material, or a combination thereof. In some embodiments, the gate stack 174 is formed using CVD, ALD, electroplating, another applicable method, or a combination thereof. The bottom transistor 100Bb may be a p-type transistor or an n-type transistor.

After the bottom transistor 100Bb is formed, a bonding structure BNB is formed over the bottom transistor 100Bb in accordance with some embodiments. More specifically, a dielectric bonding layer 202B is formed over the gate structure 168 and the interlayer dielectric layer 162, as shown in FIGS. 10E-1, 10E-2, 10E-3, and 10E-4 in accordance with some embodiments. As shown in FIGS. 10E-2 and 10E-4, the dielectric bonding layer 202B is in direct contact with the top surface of the gate structure 168 in accordance with some embodiments. In addition, the dielectric bonding layer 202B laterally extends on and in contact with the top surface of the gate spacers 140 and the top surface of the interlayer dielectric layer 162 in accordance with some embodiments. That is, the dielectric bonding layer 202B vertically overlaps both the gate structure 168 and the source/drain structures 150-1 and 150-2 in accordance with some embodiments. In some embodiments, the width of the dielectric bonding layer 202B is greater than the width of the gate structure 168 and the width of each of the source/drain structures 150-1 and 150-2 in both X direction and Y direction.

In some embodiments, the dielectric bonding layer 202B is made of a dielectric material, such as silicon oxide (SiO₂), silicon nitride (SiN), silicon oxynitride (SiON), silicon carbon nitride (SiCN), or a combination thereof. The dielectric bonding layer 202B may be formed by performing chemical vapor deposition (CVD), physical vapor deposition (PVD), atomic layer deposition (ALD), or other applicable processes.

After the dielectric bonding layer 202B is formed, conductive vias 206 are formed in the dielectric bonding layer 202B, as shown in FIGS. 10F-1, 10F-2, 10F-3, and 10F-4 in accordance with some embodiments. More specifically, openings, including openings 180-1, 180-2, and 180-3, are formed through the dielectric bonding layer 202B, and the conductive vias 206 are formed in the openings 180-1, 180-2, and 180-3 in accordance with some embodiments.

In some embodiments, the opening 180-1 is formed through the dielectric bonding layer 202B, the interlayer dielectric layer 162, and the contact etch stop layer 160 over the source/drain structure 150-1, so that the top surface of the source/drain structure 150-1 is exposed by the opening 180-1. The opening 180-1 may be formed by forming a mask layer over the dielectric bonding layer 202B, patterning the mask layer to form an opening in the mask layer, etching the dielectric bonding layer 202B through the opening, and removing the mask layer.

After the opening 180-1 is formed, the conductive via 206 is formed in the opening 180-1 in accordance with some embodiments. As shown in FIGS. 10F-1 and 10F-4, the top surface of the conductive via 206 is lower than the top surface of the dielectric bonding layer 202B in accordance with some embodiments. The formation of the conductive via 206 may include forming a silicide layer (not shown) on the exposed top surface of the source/drain structure 150-1 and forming a conductive material over the silicide layer. The silicide layer may be formed by forming a metal layer over the top surface of the source/drain structure 150-1 and annealing the metal layer so the metal layer reacts with the source/drain structure 150-1 to form the silicide layer. The unreacted metal layer may be removed after the silicide layer is formed.

After the silicide layer is formed, a conductive material is formed in the opening 180-1 in accordance with some embodiments. In some embodiments, the conductive material of the conductive via 306 is Ru, Co, W, or the like. In some embodiments, the conductive material is formed by performing a selective deposition process. That is, the conductive material may be deposited over the silicide layer in the opening 180-1 but not over the dielectric bonding layer 202B. In some embodiments, the selectively deposition of the conductive material for forming the conductive via 206 stops before the top surface of the conductive material reach the top surface of the dielectric bonding layer 202B.

In some other embodiments, the conductive material of the conductive via 206 is formed by performing a CVD, PVD, ALD, or other applicable deposition process. The conductive material will then be filled in the opening 180-1 and be formed over the top surface of the dielectric bonding layer 202B. After the conductive material is formed, a CMP process may be performed to remove the conductive material over the dielectric bonding layer 202B, so that the top surface of the dielectric bonding layer 202B is exposed. In some embodiments, the top surface of the conductive material of the conductive via 206 is lower than the top surface of the dielectric bonding layer 202B after the CMP is performed. In some other embodiments, an additional etching back process is performed to partially remove the conductive material so that the top surface of the conductive material of the conductive via 206 is lower than the top surface of the dielectric bonding layer 202B.

In some embodiments, the opening 180-2 is formed through the dielectric bonding layer 202B over the gate structure 168, so that the top surface of the gate structure 168 is exposed by the opening 180-2. After the opening 180-2 is formed, the conductive via 206 is formed in the opening 180-2, and the top surface of the conductive via 206 is lower than the top surface of the dielectric bonding layer 202B, as shown in FIGS. 10F-2 and 10F-4 in accordance with some embodiments. The formation of the conductive via 206 in the opening 180-2 may be similar to, or the same as, that of the conductive via 206 in the opening 180-1 described above, except the silicide layer is not formed. That is, the conductive material of the conductive via 206 is directly deposited on the top surface of the gate structure 168 in accordance with some embodiments.

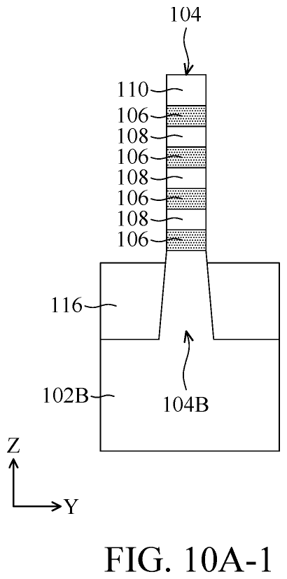

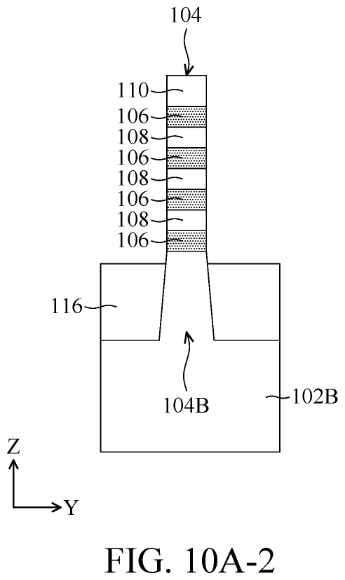

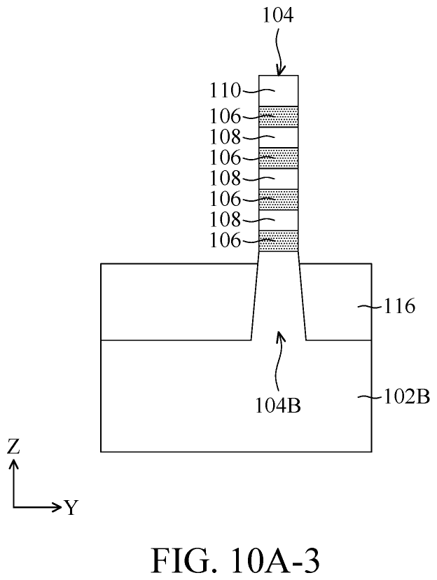

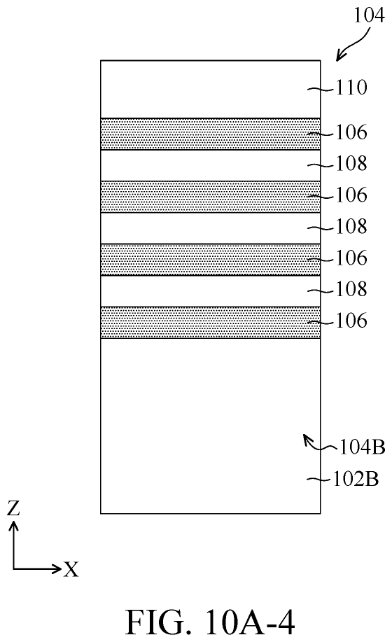

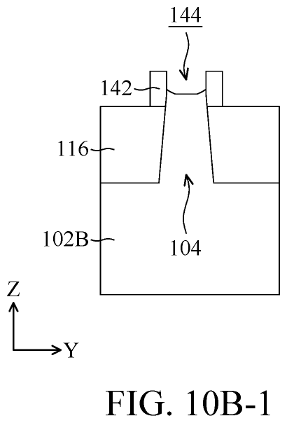

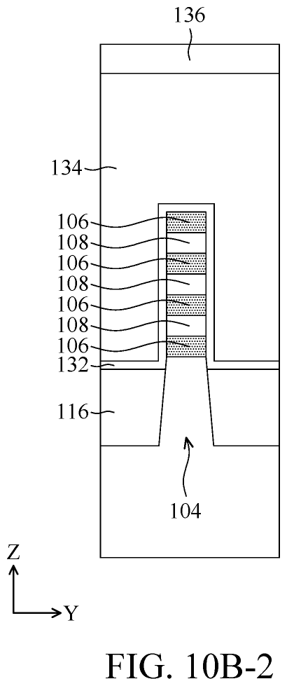

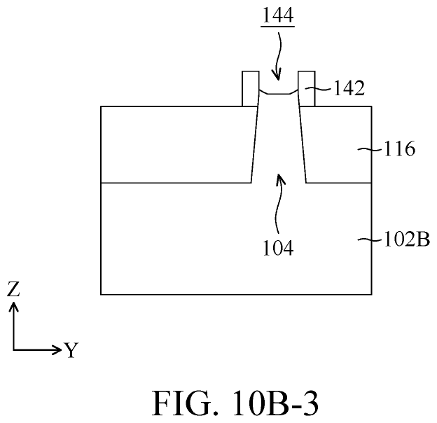

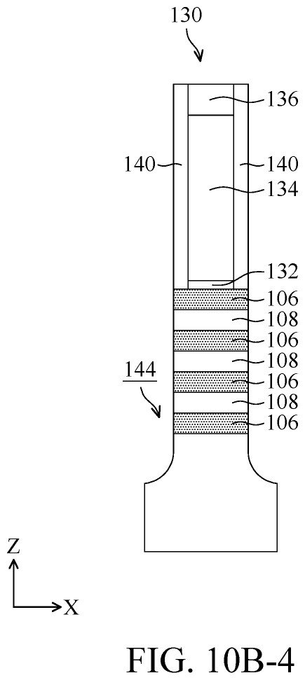

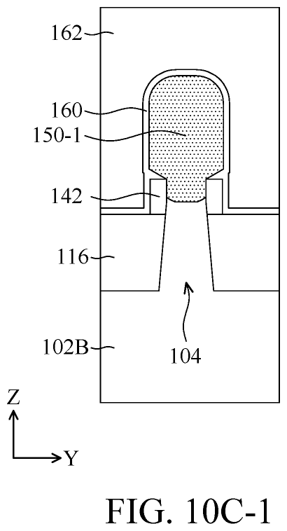

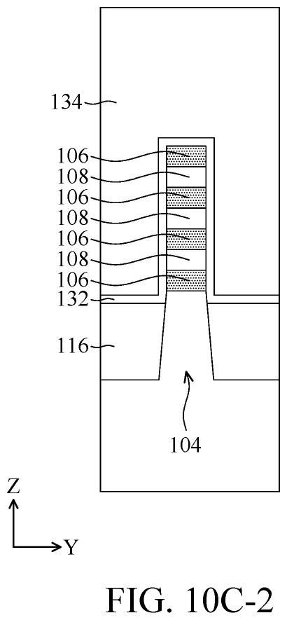

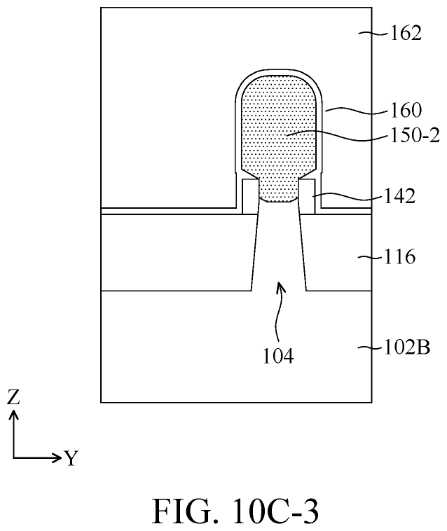

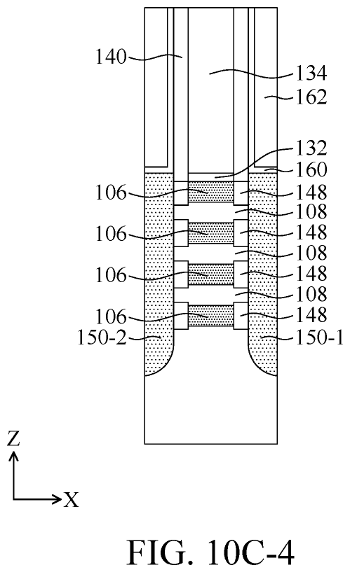

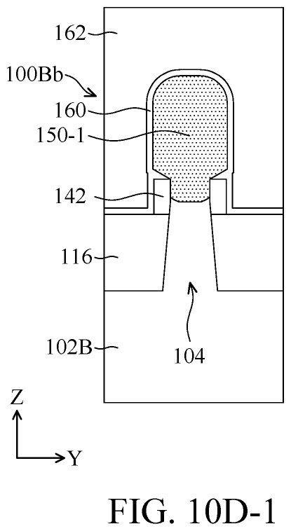

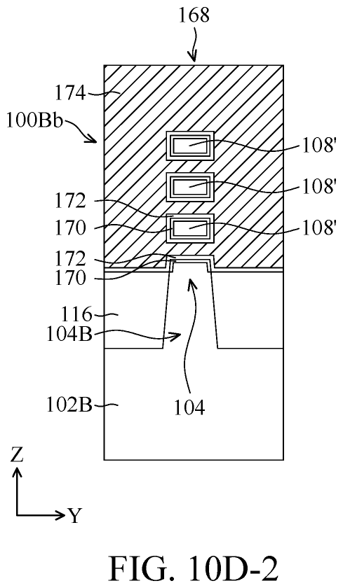

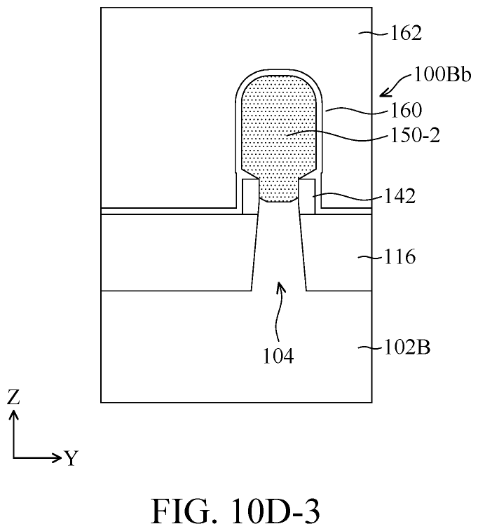

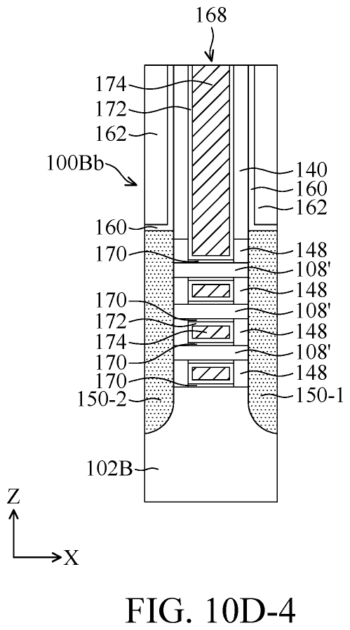

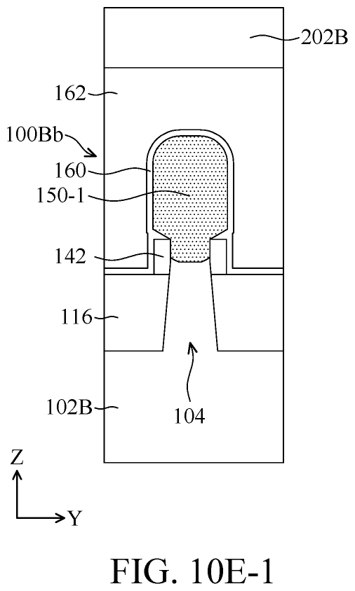

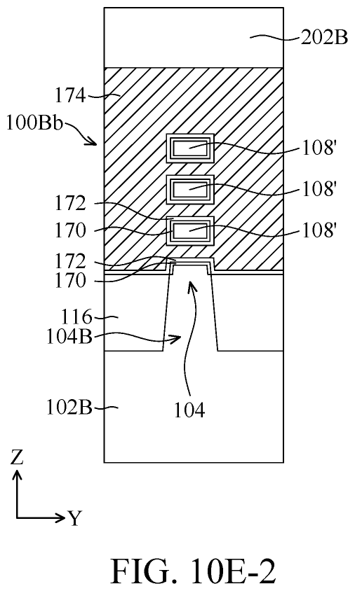

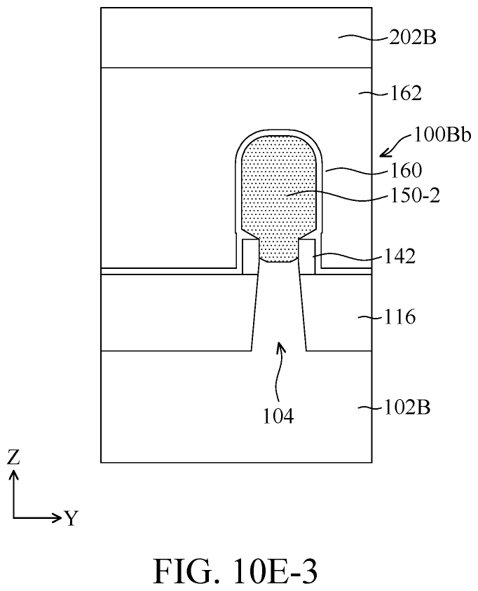

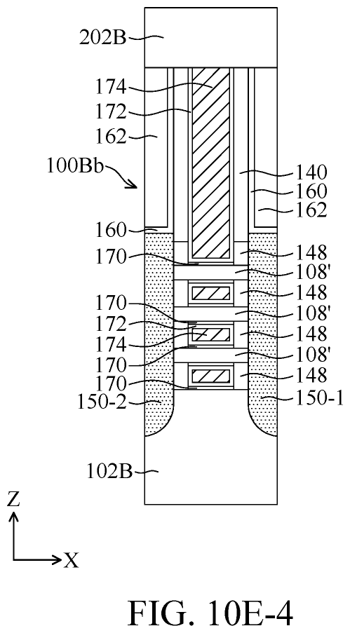

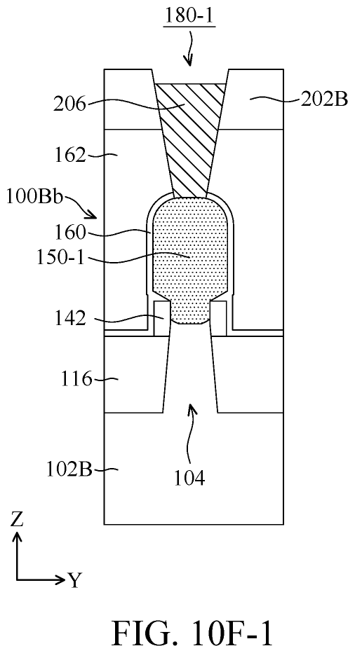

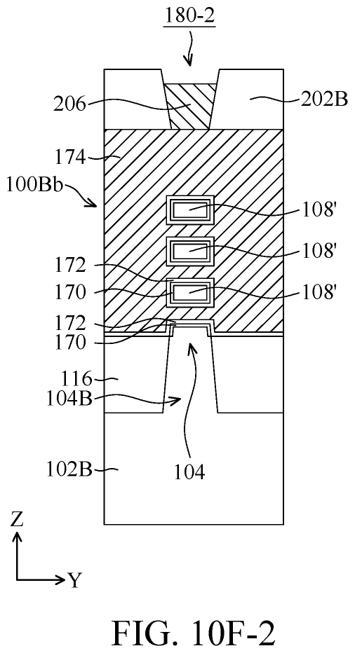

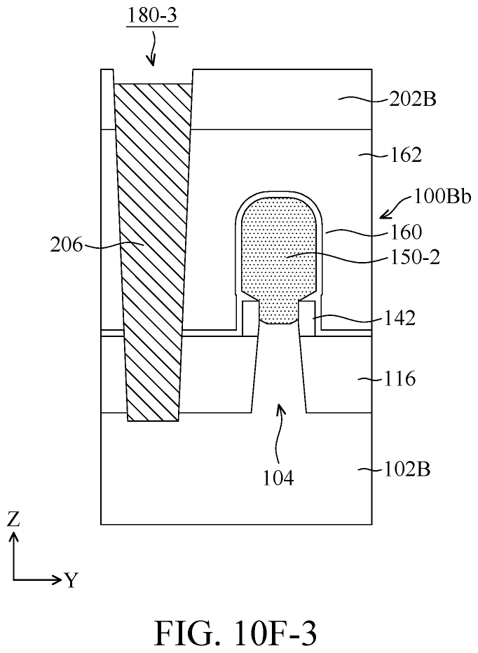

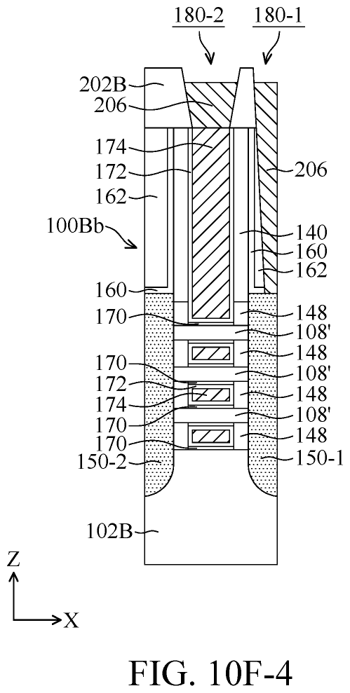

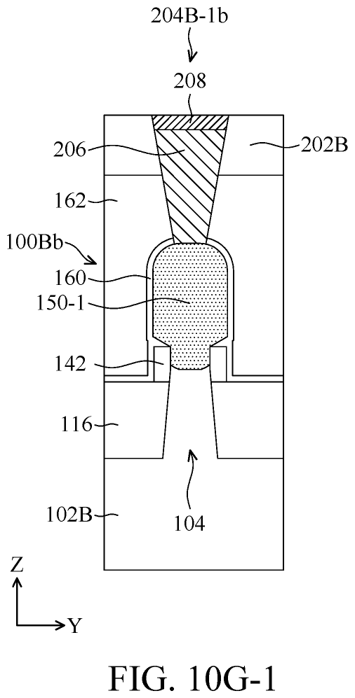

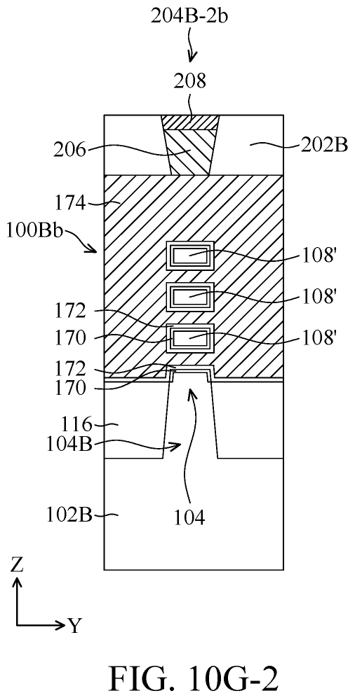

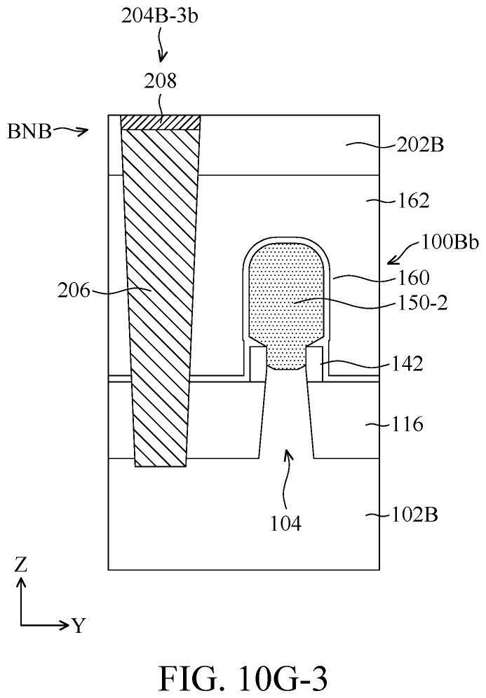

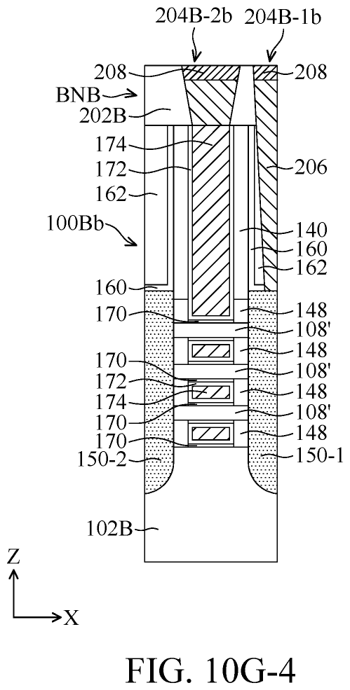

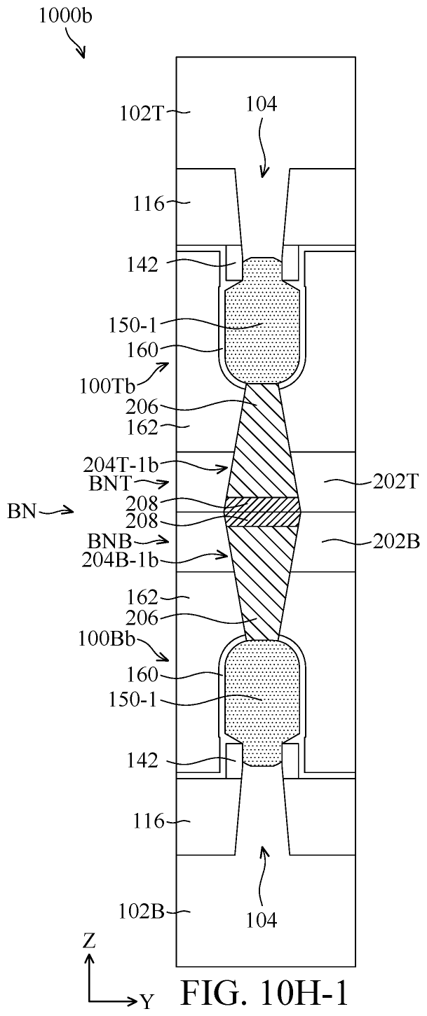

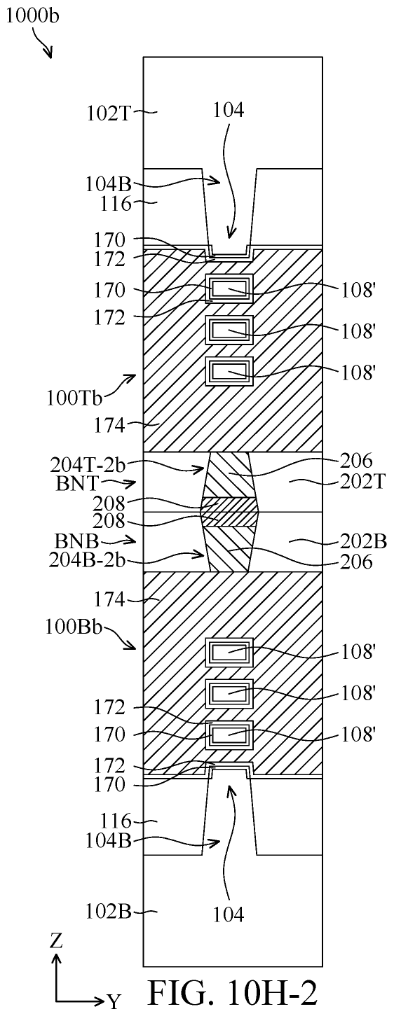

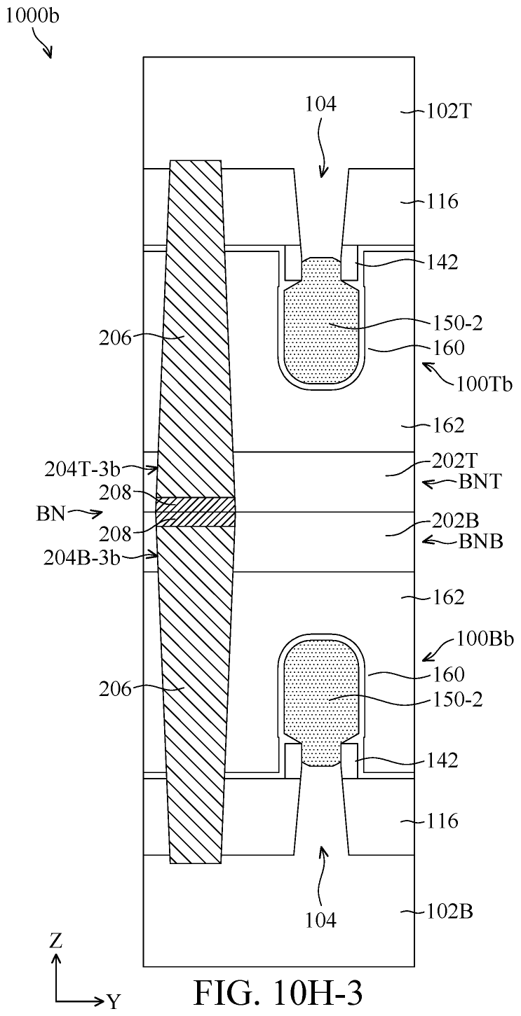

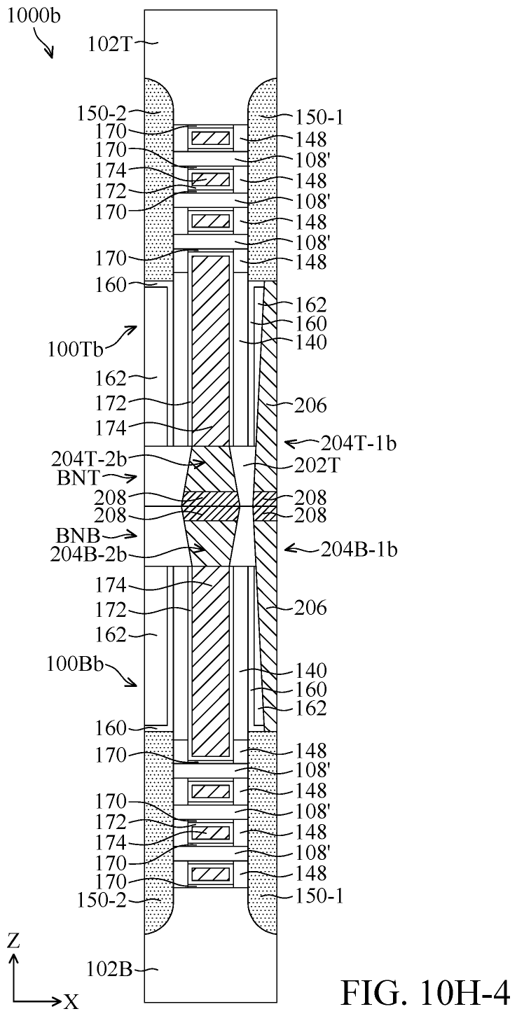

In some embodiments, the opening 180-3 is formed through the dielectric bonding layer 202B, the interlayer dielectric layer 162, the contact etch stop layer 160, and the isolation structure 116, so that the opening 180-3 partially protrudes into the substrate 102B. After the opening 180-3 is formed, the conductive via 206 is formed in the opening 180-3, and the top surface of the conductive via 206 is lower than the top surface of the dielectric bonding layer 202B, as shown in FIG. 10F-3 in accordance with some embodiments. The formation of the conductive via 206 in the opening 180-3 may be similar to, or the same as, that of the conductive via 206 in the opening 180-1 described above and is not repeated herein. In some embodiments, the openings 180-1, 180-2, 180-3 and the conductive vias 206 formed therein are formed in separated processes. In some other embodiments, the openings 180-1, 180-2, 180-3 and the conductive vias 206 formed therein are respectively formed in the same processes.

Next, the bonding pads 208 are formed over the conductive vias 206 to fill the upper regions of the openings 180-1, 180-2, and 180-3, as shown in FIGS. 10G-1, 10G-2, 10G-3, and 10G-4 in accordance with some embodiments. As described previously, the openings 180-1, 180-2, and 180-3 are not completely filled by the conductive vias 206, so that the bonding pads 208 can be formed in the upper portions of the openings 180-1, 180-2, and 180-3 in accordance with some embodiments.

In some embodiments, the bonding pads 208 are made of a conductive material different from the material for forming the conductive vias 206. In some embodiments, the bonding pads 208 are made of Co or W. In some embodiments, the conductive material of the bonding pads 208 is selectively deposited onto the conductive vias 206. That is, the conductive material is only deposited on the exposed top surface of the conductive vias 206 but not one the dielectric bonding layer 202B in accordance with some embodiments. Therefore, addition polishing process is not required. In some embodiments, the top surfaces of the bonding pads 208 are substantially level with top surface of the dielectric bonding layer 202B. In some embodiments, each of the bonding pads 208 has a thickness greater than about 5 nm so that it may have enough bonding ability in the subsequent bonding process.

As shown in FIGS. 10G-1, 10G-2, 10G-3, and 10G-4, the bonding structure BNB formed over the bottom transistor 100Bb includes the dielectric bonding layer 202B and the conductive bonding structures 204B-1b, 204B-2b, and 204B-3b formed through the dielectric bonding layer 202B in accordance with some embodiments.

In some embodiments, the conductive bonding structure 204B-1b is formed through the dielectric bonding layer 202B, the interlayer dielectric layer 162, and the contact etch stop layer 160 over the source/drain structure 150-1, so that the conductive bonding structure 204B-1b lands on the top surface of the source/drain structure 150-1. In some embodiments, the conductive bonding structure 204B-1b is in direct contact with the top surface of the source/drain structure 150-1.

In some embodiments, the conductive bonding structure 204B-2b is formed through the dielectric bonding layer 202B over the gate structure 168, so that the conductive bonding structure 204B-2b lands on the top surface of the gate structure 168. In some embodiments, the conductive bonding structure 204B-2b is in direct contact with the top surface of the gate structure 168.

In some embodiments, the conductive bonding structure 204B-3b is formed through the dielectric bonding layer 202B, the interlayer dielectric layer 162, the contact etch stop layer 160, and the isolation structure 116. In addition, the conductive bonding structure 204B-3b further extends into the substrate 102B, as shown in FIG. 10G-3 in accordance with some embodiments. That is, the bottom surface of the conductive bonding structure 204B-3b is lower than the bottom surface of the isolation structure 116.

Furthermore, as described previously, the conductive bonding structure 204B-3b is laterally spaced apart from the source/drain structure 150-2 in the Y direction, as shown in FIG. 10G-3 in accordance with some embodiments. In some embodiments, the conductive bonding structure 204B-3b is laterally spaced apart (e.g. in the Y direction) from the source/drain structure 150-2 for more than about 3 nm.

In some embodiments, the conductive bonding structures 204B-1b, 204B-2b, and 204B-3b have different heights in the Z direction. In some embodiments, the height of the conductive bonding structure 204B-3b is greater than both the height of the conductive bonding structure 204B-1b and the height of the conductive bonding structure 204B-2b in the Z direction. In some embodiments, the height of the conductive bonding structure 204B-1b is greater than the height of the conductive bonding structure 204B-2b in the Z direction. In some embodiments, the top surfaces of the conductive bonding structures 204B-1b, 204B-2b, and 204B-3b are substantially level with each other. In some embodiments, the top surfaces of the conductive bonding structures 204B-1b, 204B-2b, and 204B-3b are substantially level with the top surface of the dielectric bonding layer 202B. In some embodiments, the bottom surface of the conductive bonding structure 204B-2b is higher than both of the bottom surfaces of the conductive bonding structures 204B-1b and 204B-3b. In some embodiments, the bottom surface of the conductive bonding structure 204B-1b is higher than the bottom surface of the conductive bonding structure 204B-3b.

The processes shown in FIGS. 10A-1 to 10G-1, 10A-2 to 10G-2, 10A-3 to 10G-3, and 10A-4 to 10G-4 may be performed over another wafer to form the top transistor 100Tb over a substrate 102T. In addition, a bonding structure BNT is formed over the top transistor 100Tb in accordance with some embodiments.

The bottom transistor 100Bb and the top transistor 100Tb formed over the substrates 102B and 102T may have similar structures but have different conductivity types. For example, the bottom transistor 100Bb may be a p-type transistor, and the top transistor 100Tb may be an n-type transistor. Similar to the bonding structure BNB, the bonding structure BNT also includes a dielectric bonding layer 202T and conductive bonding structures 204Tb (including conductive bonding structures 204T-1b, 204T-2b, and 204T-3b) in accordance with some embodiments. The processes and materials for forming the bonding structure BNT (including the dielectric bonding layer 202T and the conductive bonding structures 204Tb), the top transistor 100T, and the substrate 102T may be similar to, or the same as, those for forming the bonding structure BNB (including the dielectric bonding layer 202B and the conductive bonding structures 204b), the bottom transistor 100Bb, and the substrate 102B described previously and are not repeated herein.

The substrate 102B may be seen as a first wafer, the substrate 102T may be seen as a second wafer, and the second wafer may be bonded to the first wafer to form the CFET structure 1000b. More specifically, after the top transistor 100Tb is formed, the second substrate 102Tb is flipped upside down, and the bonding structure BNT formed over the top transistor 100Tb is bonded to the bonding structure BNB, as shown in FIGS. 10H-1, 10H-2, 10H-3, and 10H-4 in accordance with some embodiments. In addition, the top transistor 100Tb and the bottom transistor 100Bb are bonded together through hybrid bonding, including dielectric-to-dielectric bonding and metal-to-metal bonding in accordance with some embodiments. That is, the dielectric bonding layer 202B in the bonding structure BNB is directly bonded to (i.e. in direction contact with) the dielectric bonding layer 202T in the bonding structure BNT in accordance with some embodiments. In addition, the conductive bonding structures 204B-1b, 204B-2b, and 204B-3b in the bonding structure BNB is directly bonded to (i.e. in direction contact with) the conductive bonding structures 204T-1b, 204T-2b, and 204T-3b in the bonding structure BNT in accordance with some embodiments. In some embodiments, the hybrid process is achieved by performing an annealing process. In some embodiments, the annealing process is performed under about 200° C. to about 400° C. for about 30 minutes to about 6 hours.

In some embodiments, the bonding pad 208 of the conductive bonding structure 204B-1b in the bonding structure BNB is directly bonded to (i.e. in direction contact with) the bonding pad 208 of the conductive bonding structure 204T-1b in the bonding structure BNT, as shown in FIGS. 10H-1 and 10H-4. In some embodiments, the bonding pad 208 of the conductive bonding structure 204B-2b in the bonding structure BNB is directly bonded to (i.e. in direction contact with) the bonding pad 208 of the conductive bonding structure 204T-2b in the bonding structure BNT, as shown in FIGS. 10H-2 and 10H-4. In some embodiments, the bonding pad 208 of the conductive bonding structure 204B-3b in the bonding structure BNB is directly bonded to (i.e. in direction contact with) the bonding pad 208 of the conductive bonding structure 204T-3b in the bonding structure BNT, as shown in FIG. 10H-3. The bonding structure BNB and the bonding structure BNT may be seen as a bonding structure BN.

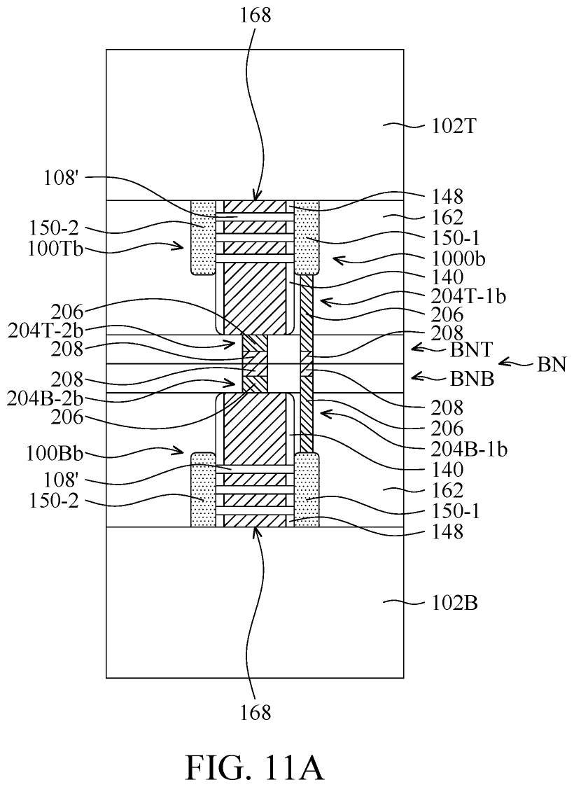

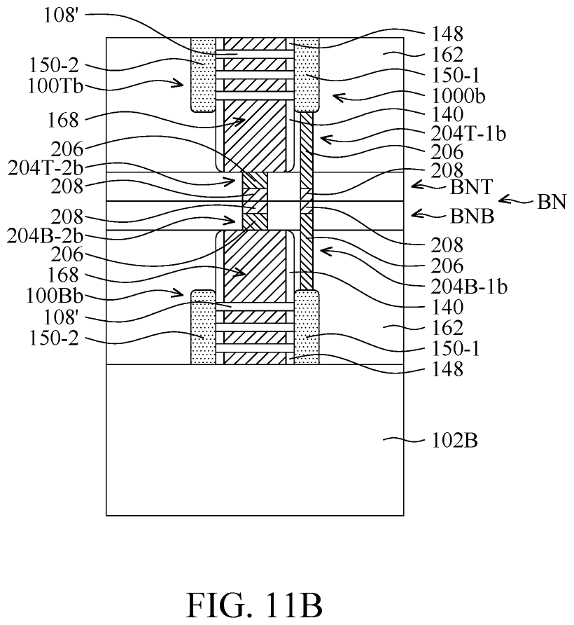

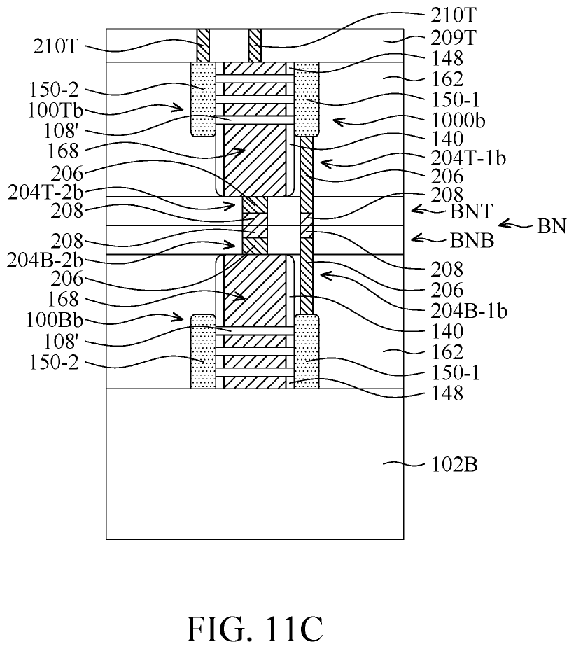

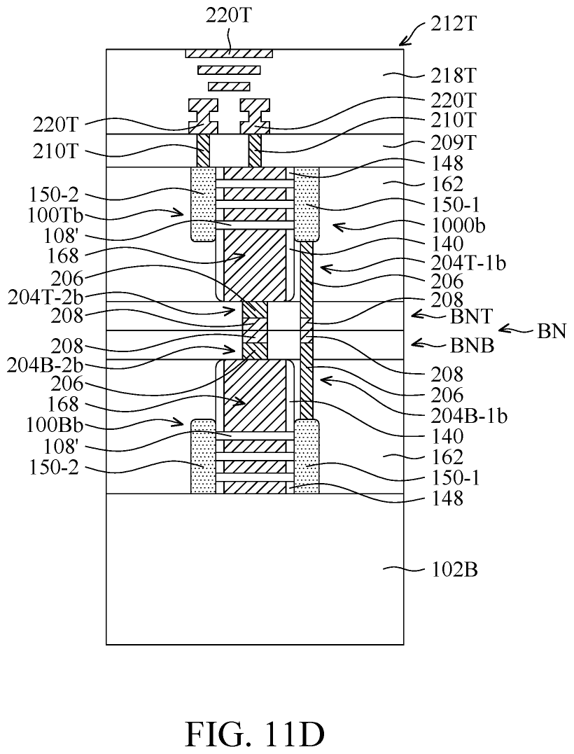

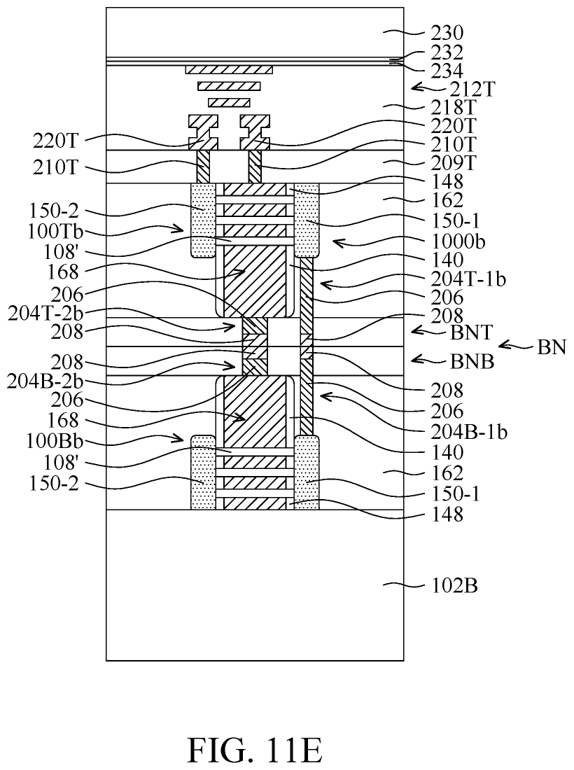

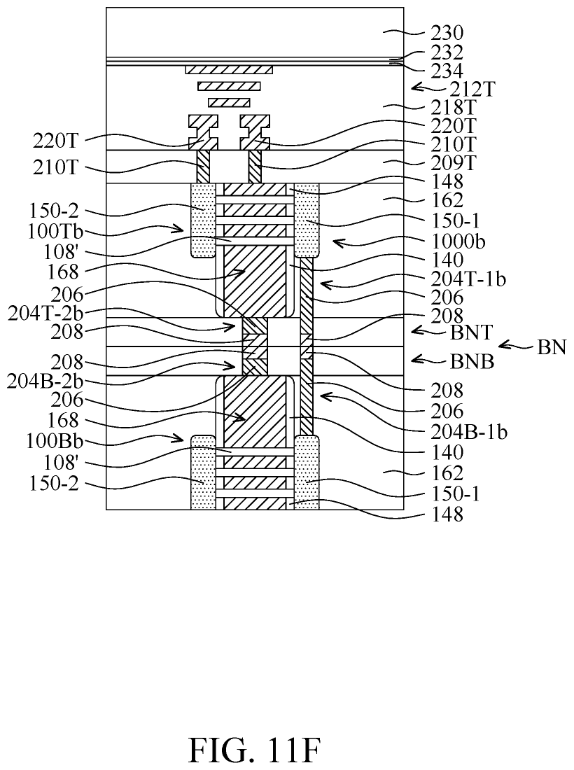

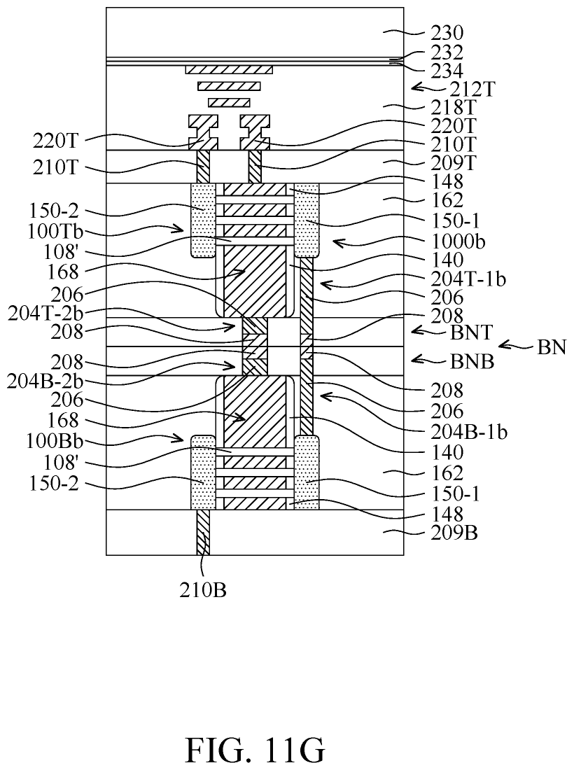

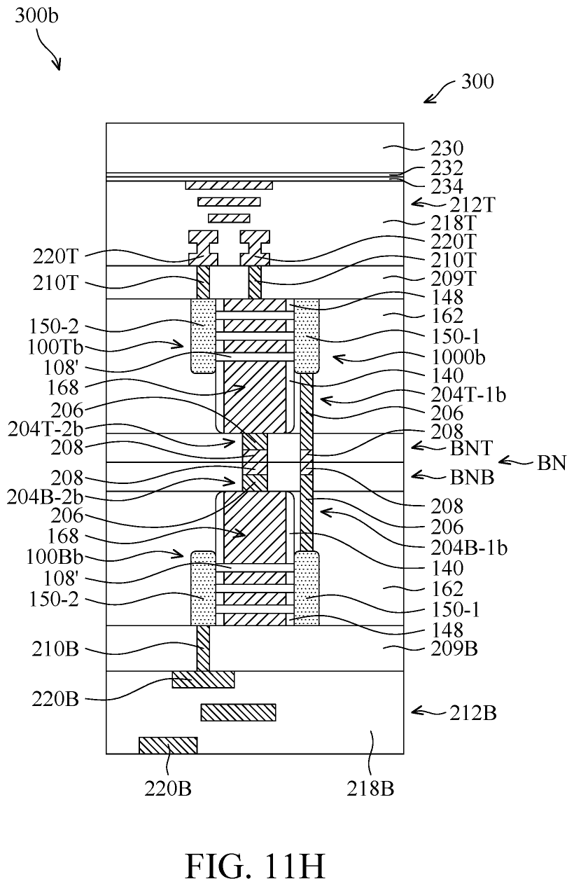

FIGS. 11A to 11H illustrate the cross-sectional views of intermediate stages of manufacturing the package structure 300b in accordance with some embodiments. As described previously, the first wafer (e.g. the substrate 102B) and the second wafer (e.g. the substrate 102T) may be bonded together, and the package structure 300b may then be formed. The structure shown in FIG. 11A may include the CFET structure 1000b shown in FIGS. 10H-1, 10H-2, 10H-3, and 10H-4 described previously, although some portions of the top transistor 100Tb and the bottom transistor 100Bb in the CFET structure 1000b are simplified for clarity. That is, the detail structures and the method for manufacturing the CFET structure 1000b shown in FIGS. 11A to 11H may be similar to, or the same as, those shown in FIGS. 2A to 2C, 9, 10A-1 to 10H-1, 10A-2 to 10H-2, 10A-3 to 10H-3, and 10A-4 to 10H-4 and described previously and are not repeated herein.

As shown in FIG. 11A, the top transistor 100Tb is bonded to the bottom transistor 100Bb using the hybrid-bonding structure in accordance with some embodiments. In addition, the top transistor 100Tb is flipped upside down before bonding to the bottom transistor 100Bb, the substrate 102B and the substrate 102T are at opposite sides of the top transistor 100Tb and the bottom transistor 100Bb in accordance with some embodiments. As shown in FIG. 11A, the front side of the top transistor 100Tb faces the front side of the bottom transistor 100Bb in accordance with some embodiments.

After the top transistor 100Tb is bonded to the bottom transistor 100Bb, a planarization process is performed over the substrate 102T, as shown in FIG. 11B in accordance with some embodiments. In some embodiments, the planarization process is performed to the substrate 102T until the isolation structure 116 (not shown in FIG. 11B) is exposed. In some embodiments, the substrate 102T is completely removed after planarization process is performed.

Next, a dielectric layer 209T is formed over the backside of the top transistor 100Tb, and the backside vias 210T are formed through the dielectric layer 209T, as shown in FIG. 11C in accordance with some embodiments. In some embodiments, the dielectric layer 209T is made of a low k dielectric material having a k value lower than 7. In some embodiments, the dielectric layer 209T is made of SiO₂, SiN, SiCN, SiOC, SiOCN, or the like. The dielectric layer 209T may be formed by chemical vapor deposition (CVD), physical vapor deposition, (PVD), atomic layer deposition (ALD), or other applicable processes.

After the dielectric layer 209T is formed, backside trenches may be formed through the dielectric layer 209T. In addition, bottom portions of the source/drain structures 150-2, the conductive bonding structure 204T-2b, and the gate structure 168 of the top transistor 100Tb may be exposed by the backside vias. In some embodiments, the bottom portions of the source/drain structure 150-2, the conductive bonding structure 204T-2b, and the gate structure 168 are also slightly removed. Afterwards, the backside vias 210T are formed in the backside trenches, so that the backside vias 210T are electrically connected to the backside of the top transistor 100Tb in accordance with some embodiments. In some embodiments, one of the backside vias 210T is in contact with the backside of the gate structure 168 of the top transistor 100Tb. In some embodiments, one of the backside vias 210T is in contact with the backside of the source/drain structure 150-2 of the top transistor 100Tb. In some embodiments, one of the backside vias 210T is in contact with the backside of one of the conductive bonding structures 204T-3b adjacent to the source/drain structure 150-2. In some embodiments, the backside vias 210T and the conductive bonding structures 204T-1b and 204T-2b are at opposite sides of the top transistor 100Tb.

The backside vias 210T may include backside silicide layers (not shown) and conductive filling layers formed over the backside silicide layers. In some embodiments, the backside silicide layers are N-type epi silicide such as TiSi, CrSi, TaSi, MoSi, ZrSi, HfSi, ScSi, Ysi, HoSi, TbSI, GdSi, LuSi, DySi, ErSi, YbSi, or the like. In some embodiments, the backside silicide layers are P-type epi silicide such as NiSi, CoSi, MnSi, Wsi, FeSi, RhSi, PdSi, RuSi, PtSi, IrSi, OsSi, or the like.

After the backside silicide layers are formed, the conductive filling layer is formed to fill the backside trenches, and a polishing process is performed to form the backside vias 210T, as shown in FIG. 11C in accordance with some embodiments. In some embodiments, the conductive filling layer are made of W, Ru, Co, Cu, Ti, TiN, Ta, TaN, Mo, Ni, other applicable conductive materials, or a combination thereof. The conductive filling layer may be formed using a process such as chemical vapor deposition (CVD), physical vapor deposition (PVD), plasma enhanced CVD (PECVD), plasma enhanced physical vapor deposition (PEPVD), atomic layer deposition (ALD), or any other applicable deposition processes.

A liner layer (not shown) and/or a barrier layer (not shown) may be formed on the sidewalls of the backside vias 210T. For example, the liner layer may include silicon nitride, although any other applicable dielectric may be used as an alternative. For example, the barrier layer may include tantalum nitride, although other materials, such as tantalum, titanium, titanium nitride, or the like, may also be used. The liner layer and the barrier layers may be formed using a process such as chemical vapor deposition (CVD), physical vapor deposition (PVD), plasma enhanced CVD (PECVD), plasma enhanced physical vapor deposition (PEPVD), atomic layer deposition (ALD), or another applicable deposition processes.

After the backside vias 210T are formed, an interconnect structure 212T is formed over the backside vias 210T and over the backside of the top transistor 100Tb, as shown in FIG. 11D in accordance with some embodiments. In some embodiments, the interconnect structure 212T is a backside interconnect structure. In some embodiments, the interconnect structure 212T includes multiple dielectric layers 218T and conductive structures 220T (e.g. vias and metal lines) formed in multiple dielectric layers 218T.

In some embodiments, the backside vias 210T are electrically connected to the conductive structures 220T in the interconnect structure 212T. As shown in FIG. 11D, the conductive structures 220T in the interconnect structure 212T are electrically connected to the top transistor 100Tb through the backside vias 210T in accordance with some embodiments. In addition, the backside via 210T connected to the backside of the source/drain structure 150-2 is electrically connected to the backside via 210T connected to the backside of the conductive bonding structure 204B-3b through the conductive structures 220T of the interconnect structure 212T (not shown in FIG. 11D, see FIG. 2B) in accordance with some embodiments.

The dielectric layer 218T may include multilayers made of multiple dielectric materials, such as silicon oxide, silicon nitride, silicon oxynitride, phosphosilicate glass (PSG), borophosphosilicate glass (BPSG), and/or other applicable low-k dielectric materials. The dielectric layer 218T may be formed by chemical vapor deposition (CVD), physical vapor deposition, (PVD), atomic layer deposition (ALD), or other applicable processes.

In some embodiments, the conductive structures 220T are made of conductive materials, such as copper (Cu), copper alloy, aluminum (Al), aluminum alloys, combinations thereof or another applicable material. In some embodiments, the conductive structures 220T are formed by chemical vapor deposition (CVD), physical vapor deposition (PVD), plasma enhanced CVD (PECVD), plasma enhanced physical vapor deposition (PEPVD), atomic layer deposition (ALD), or another applicable deposition processes.

After the interconnect structure 212T is formed, a carrier substrate 230 is attached to the interconnect structure 212T to provide the semiconductor structure with mechanical and structural support in subsequent manufacturing process. The carrier substrate 230 may include glass, silicon oxide, aluminum oxide, metal, a combination thereof, and/or the like. In some embodiments, the interconnect structure 212T is attached to the carrier substrate 230 by fusion bonding. In some embodiments, an adhesive layer 232 is formed over the carrier substrate 230, an adhesive layer 234 is formed over the interconnect structure 212T, and the carrier substrate 230 is bonded to the interconnect structure 212T through bonding the adhesive layers 232 and 234. The adhesive layers 232 and 234 may be glue or tapes.

After the carrier substrate 230 is attached to the interconnect structure 212T, a planarization process is performed on the substrate 102B, as shown in FIG. 11F in accordance with some embodiments. In some embodiments, the planarization process is performed to the substrate 102B until the isolation structure 116 (not shown in FIG. 11F) is exposed. In some embodiments, the substrate 102B is completely removed after planarization process is performed.

Next, a dielectric layer 209B is formed over the backside of the bottom transistor 100Bb, and backside vias 210B are formed through the dielectric layer 209B, as shown in FIG. 11G in accordance with some embodiments. The processes and materials for forming the dielectric layer 209B and the backside vias 210B may be similar to, or the same as, those for forming the dielectric layer 209T and the backside vias 210T described previously and are not repeated herein.

After the backside vias 210B are formed, an interconnect structure 212B is formed over the backside vias 210B and over the backside of the bottom transistor 100Bb, as shown in FIG. 11H in accordance with some embodiments. The processes and materials for forming the interconnect structure 212B may be similar to, or the same as, those for forming the interconnect structure 212T described previously and are not repeated herein.

In some embodiments, the interconnect structure 212B includes multiple dielectric layers 218B and conductive structures 220B (e.g. vias and metal lines) formed in multiple dielectric layers 218B. In some embodiments, the backside vias 210B are electrically connected to the conductive structures 220B in the interconnect structure 212B. As shown in FIG. 11D, the conductive structures 220B in the interconnect structure 212B are electrically connected to the bottom transistor 100Bb through the backside vias 210B in accordance with some embodiments. In addition, the backside via 210B connected to the backside of the source/drain structure 150-2 is electrically connected to the backside via 210B connected to the backside of the conductive bonding structure 204B-3 through the conductive structures 220B of the interconnect structure 212B (see FIG. 2B) in accordance with some embodiments.

As shown in FIG. 11H, the package structure 300b includes the CFET structure 1000b formed therein in accordance with some embodiments. In addition, the CFET structure 1000b includes the bottom transistor 100Bb formed over the first wafer and the top transistor 100Tb formed over the second wafer in accordance with some embodiments. In some embodiments, the bottom transistor 100Bb is a p-type transistor, and the top transistor 100Tb is an n-type transistor. In some embodiments, the bottom transistor 100Bb is an n-type transistor, and the top transistor 100Tb is a p-type transistor. The top transistor 100Tb and the bottom transistor 100Bb may individually include at least one channel layer 108′ and the gate structure 168 wrapping around the channel layer 108′. The bonding structure BN, including the bonding structure BNB and the bonding structure BNT, is vertically sandwiched between the top transistor 100Tb and the bottom transistor 100Bb in accordance with some embodiments.

In some embodiments, the bonding structure BN includes the dielectric bonding layer 202B attached to the gate structure 168 of the bottom transistor 100Bb, the conductive bonding structures 204B formed through the dielectric bonding layer 202B, the dielectric bonding layer 202T attached to the dielectric bonding layer 202B and the gate structure 168 of the top transistor 100Tb, and the conductive bonding structures 204T formed through the dielectric bonding layer 202T and bonded to the conductive bonding structures 204B.

In addition, the backside vias 210T are electrically connected to the top transistor 100Tb, and the backside vias 210Ba are electrically connected to the bottom transistor 100Bb in accordance with some embodiments. Furthermore, the interconnect structure 212T is formed over the backside vias 210T, and the interconnect structure 212B is formed over the backside vias 210B in accordance with some embodiments. The interconnect structure 212T and the interconnect structure 212B at opposite sides of the top transistor 100Tb and the bottom transistor 100Bb in accordance with some embodiments. In some embodiments, the closest distance between the gate structure 168 of the top transistor 100Tb and the gate structure 168 of the bottom transistor 100Bb is substantially equal to the sum of the thickness of the dielectric bonding layer 202B and the thickness of the dielectric bonding layer 202T in the Z direction. In some embodiments, the interconnect structure 212B and the top transistor 100Tb are at opposite sides of the bottom transistor 100Bb in the Z direction, and the interconnect structure 212T and the bottom transistor 100Bb are at opposite sides of the top transistor 100Tb in the Z direction.

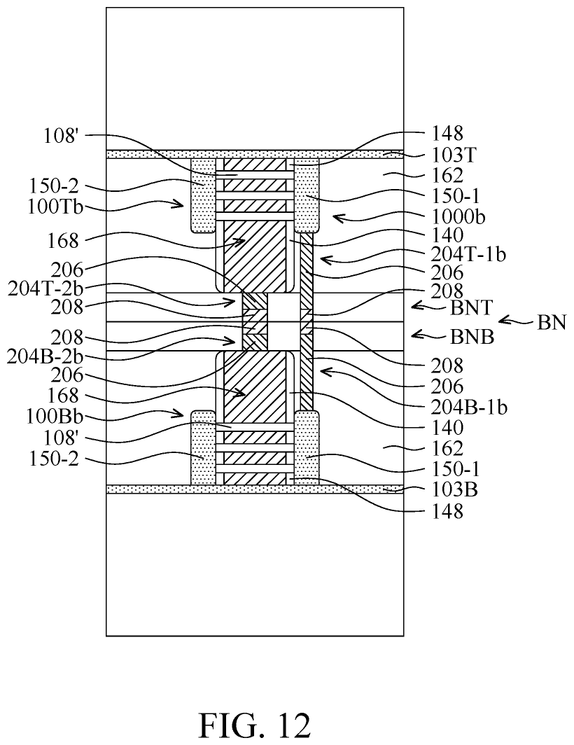

FIG. 12 illustrates a cross-sectional view of an intermediate stage of manufacturing the package structure 300b in accordance with some other embodiments. The structure shown in FIG. 12 is substantially the same as the structure shown in FIG. 11A, except additional sacrificial layers are formed. More specifically, a sacrificial layer 103B is formed over the substrate 102B before the bottom transistor 100Bb is formed, and a sacrificial layer 103T is formed over the substrate 102T before the top transistor 100Tb is formed in accordance with some embodiments.

The sacrificial layers 103B and 103T may be configured to use as etch stop layers during the planarization processes for removing the substrates 102B and 102T in accordance with some embodiments. That is, during the planarization processes shown in FIGS. 11B and 11F, the sacrificial layers 103T and 103B are used as etch stop layers, so that the planarization processes stop when the sacrificial layers 103T and 103B are exposed. Afterwards, the sacrificial layers 103T and 103B may be removed. Other than the sacrificial layers 103T and 103B, processes shown in FIGS. 11A to 11H may be performed to form the package structure 300b. In some embodiments, the sacrificial layers 103B and 103T are both SiGe layers.

As described previously, an nFET transistor (e.g. the top transistors 100Ta to 100Th) and a pFET transistor (e.g. the bottom transistors 100Ba to 100Bh) may be formed separately on two wafers. The two wafers may be bonded together through hybrid-bonding, so that the nFET transistor and the pFET transistor may be bonded to form a CFET transistor (e.g. the CFET structures 1000a to 1000h). Since the nFET transistor and the pFET transistor are formed separately, the transistor formed first will not be damaged due to the manufacturing processes (e.g. thermal processes) for forming the transistor formed afterwards. Therefore, the performance of the resulting CFET structure may be improved.

The hybrid-bonding may include dielectric-to-dielectric bonding and metal-to-metal bonding. In some embodiments, the metal-to-metal bonding is realized by bonding the conductive bonding structures (e.g. the conductive bonding structures 204T-1a to 204T-1h, 204T-2a to 204T-2h, 204T-3a to 204T-3h, 204B-1a to 204B-1h, 204B-2a to 204B-2h, and 204B-3a to 204B-3h).

Since the conductive bonding structures may have relatively small size, the conductive bonding structures may be made of conductive material such as ruthenium, cobalt, or tungsten. These conductive materials may have lower resistance at smaller sizes, compared to copper, and therefore the performance of the resulting devices may be improved. In addition, since the conductive bonding structures are first formed at different wafers and are bonded together afterwards, the aspect ratio of these conductive bonding structures may be relatively small, compared to the via structures in a CFET structure formed by the monolithic approach. Furthermore, the conductive materials of the conductive bonding structures may be formed by selective deposition, and therefore the topography may be better controlled and the yield may therefore be improved.

It should be appreciated that the elements shown in the transistor 100a to 100h may be combined and/or exchanged. In addition, it should be noted that same elements in FIGS. 1A to 12 may be designated by the same numerals and may include materials that are the same or similar and may be formed by processes that are the same or similar; therefore such redundant details are omitted in the interests of brevity. In addition, although FIGS. 1A to 12 are described in relation to the method, it will be appreciated that the structures disclosed in FIGS. 1A to 12 are not limited to the method but may stand alone as structures independent of the method. Similarly, the methods shown in FIGS. 1A to 12 are not limited to the disclosed structures but may stand alone independent of the structures. Furthermore, the channel layers (e.g. the nanostructures) described above may include nanowires, nanosheets, or other applicable nanostructures in accordance with some embodiments.

Also, while the disclosed methods are illustrated and described above as a series of acts or events, it should be appreciated that the illustrated ordering of such acts or events may be altered in some other embodiments. For example, some acts may occur in a different order and/or concurrently with other acts or events apart from those illustrated and/or described above. In addition, not all illustrated acts may be required to implement one or more aspects or embodiments of the description above. Furthermore, one or more of the acts depicted above may be carried out as one or more separate acts and/or phases.

Furthermore, the terms “approximately,” “substantially,” “substantial” and “about” used above account for small variations and may be varied in different technologies and be within the deviation range understood by the skilled in the art. For example, when used in conjunction with an event or circumstance, the terms can refer to instances in which the event or circumstance occurs precisely as well as instances in which the event or circumstance occurs in a close approximation.

Embodiments for forming semiconductor structures may be provided. The semiconductor structure may include forming a bottom transistor and a top transistor over two separated wafers. The top transistor may then be bonded to the bottom transistor through a bonding structure. In addition, a bonding structure may include a first conductive bonding structure formed over the bottom transistor and a second conductive bonding structure formed over the top transistor. The first conductive bonding structure may by bonded to the second conductive structure. Since the bottom transistor and the top transistor are formed separately, the manufacturing processes may be simplified and the performance of the resulting device may be improved.

In some embodiments, a semiconductor structure is provided. The semiconductor structure includes a first transistor. The first transistor includes a first channel layer and a first gate structure wrapping around the first channel layer. The semiconductor transistor further includes a second transistor. The second transistor includes a second channel layer and a second gate structure wrapping around the second channel layer. The semiconductor transistor further includes a bonding structure vertically sandwiched between the first transistor and the second transistor. The bonding structure includes a first dielectric bonding layer attached to the first gate structure and a first conductive bonding structure formed through the first dielectric bonding layer. The bonding structure further includes a second dielectric bonding layer attached to the first dielectric bonding layer and the second gate structure and a second conductive bonding structure formed through the second dielectric bonding layer and bonded to the first conductive bonding structure.

In some embodiments, a semiconductor structure is provided. The semiconductor structure includes a p-type transistor. The p-type transistor includes a first channel layer and a first source/drain structure and a second source/drain structure attached to opposite sides of the first channel layer in a first direction. The p-type transistor further includes a first gate structure wrapping around the first channel layer and extending in a second. The semiconductor structure further includes a first conductive bonding structure bonded to the p-type transistor and a second conductive bonding structure bonded to the first conductive bonding structure in a third direction. The semiconductor structure further includes an n-type transistor bonded to the second conductive bonding structure. The n-type transistor includes a second channel layer and a third source/drain structure and a fourth source/drain structure attached to opposite sides of the second channel layer. The n-type transistor further includes a second gate structure wrapping around the second channel layer.

In some embodiments, a method for manufacturing a semiconductor structure is provided. The method includes forming a first transistor over a first substrate, and the first transistor includes a first channel layer and a first gate structure abutting the first channel layer. The method also includes forming a first dielectric bonding layer covering a top surface of the first gate structure, and a first conductive bonding structure is formed through the first dielectric bonding layer and electrically connected to the first transistor. The method also includes forming a second transistor over a second substrate, and the second transistor includes a second channel layer and a second gate structure abutting the second channel layer. The method also includes forming a second dielectric bonding layer covering a top surface of the second gate structure, and a second conductive bonding structure is formed through the second dielectric bonding layer and electrically connected to the second transistor. The method also includes bonding the first dielectric bonding layer to the second dielectric bonding layer and bonding the first conductive bonding structure to the second conductive bonding structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a first transistor, wherein the first transistor comprises:
a first channel layer; and
a first gate structure wrapping around the first channel layer;
a second transistor, wherein the second transistor comprises:
a second channel layer; and
a second gate structure wrapping around the second channel layer;
a bonding structure vertically sandwiched between the first transistor and the second transistor, wherein the bonding structure comprises:
a first dielectric bonding layer attached to the first gate structure;
a first conductive bonding structure formed through the first dielectric bonding layer;
a second dielectric bonding layer attached to the first dielectric bonding layer and the second gate structure; and
a second conductive bonding structure formed through the second dielectric bonding layer and bonded to the first conductive bonding structure.

2. The semiconductor structure as claimed in claim 1, further comprising:
first source/drain structures attached to opposite sides of the first channel layer; and
second source/drain structures attached to opposite sides of the second channel layer,
wherein the first dielectric bonding layer laterally extends from a top surface of the first gate structure to vertically overlap the first source/drain structures.

3. The semiconductor structure as claimed in claim 2, further comprising:
a first backside via connected to a first one of the first source/drain structures, wherein the first backside via and the first conductive bonding structure are located at opposite sides of the first transistor.

4. The semiconductor structure as claimed in claim 3, wherein the first conductive bonding structure is electrically connected to a second one of the first source/drain structures.

5. The semiconductor structure as claimed in claim 3, wherein the first conductive bonding structure is in contact with the first gate structure.

6. The semiconductor structure as claimed in claim 3, further comprising
a first interconnect structure attached to the first backside via;
a second backside via connected to the second source/drain structures; and
a second interconnect structure attached to the second backside via,
wherein the first interconnect structure and the second interconnect structure are at opposite sides of the first transistor and the second transistor.

7. A semiconductor structure, comprising:
a p-type transistor, wherein the p-type transistor comprises:
a first channel layer;
a first source/drain structure and a second source/drain structure attached to opposite sides of the first channel layer in a first direction; and
a first gate structure wrapping around the first channel layer and extending in a second direction;
a first conductive bonding structure bonded to the p-type transistor;
a second conductive bonding structure bonded to the first conductive bonding structure in a third direction; and
an n-type transistor bonded to the second conductive bonding structure, wherein the n-type transistor comprises:
a second channel layer;
a third source/drain structure and a fourth source/drain structure attached to opposite sides of the second channel layer; and
a second gate structure wrapping around the second channel layer.

8. The semiconductor structure as claimed in claim 7, further comprising:
a first dielectric bonding layer bonded to the p-type transistor in the third direction; and
a second dielectric bonding layer bonded to the first dielectric bonding layer and the n-type transistor,
wherein the first conductive bonding structure is formed through the first dielectric bonding layer, and the second conductive bonding structure is formed through the second dielectric bonding layer.

9. The semiconductor structure as claimed in claim 8, wherein a closest distance between the first gate structure and the second gate structure is substantially equal to a sum of a thickness of the first dielectric bonding layer and a thickness of the second dielectric bonding layer in the third direction.

10. The semiconductor structure as claimed in claim 7, wherein the first conductive bonding structure is spaced apart from the second source/drain structure in the first direction or in the second direction but is electrically connected to the second source/drain structure.

11. The semiconductor structure as claimed in claim 7, wherein the first conductive bonding structure is in contact with the first gate structure, and the second conductive bonding structure is in contact with the second gate structure in the third direction.

12. The semiconductor structure as claimed in claim 11, further comprising:
a third conductive bonding structure electrically connected to the first source/drain structure; and
a fourth conductive bonding structure bonded to the third conductive bonding structure in the third direction and electrically connected to the third source/drain structure,
wherein a thickness of the third conductive bonding structure in the third direction is greater than a thickness of the first conductive bonding structure in the third direction.

13. The semiconductor structure as claimed in claim 7, wherein the first conductive bonding structure is in contact with the first source/drain structure in the third direction.

14. The semiconductor structure as claimed in claim 7, wherein the first conductive bonding structure comprises:
a first conductive via; and
a first bonding pad formed over the first conductive via,
wherein the first conductive via and the first bonding pad are made of different conductive materials.

15. The semiconductor structure as claimed in claim 7, further comprising:
a first backside conductive via electrically connected to the p-type transistor; and
a first interconnect structure attached to the first backside conductive via,
wherein the first interconnect structure and the n-type transistor are at opposite sides of the p-type transistor in the third direction.

16. The semiconductor structure as claimed in claim 15, further comprising:
a second backside conductive via electrically connected to the n-type transistor; and
a second interconnect structure attached to the second backside conductive via,
wherein the second interconnect structure and the first interconnect structure are at opposite sides of the n-type transistor in the third direction.

17. A method for forming a semiconductor structure, comprising:
forming a first transistor over a first substrate, wherein the first transistor comprises a first channel layer and a first gate structure abutting the first channel layer;
forming a first dielectric bonding layer covering a top surface of the first gate structure, wherein a first conductive bonding structure is formed through the first dielectric bonding layer and electrically connected to the first transistor;
forming a second transistor over a second substrate, wherein the second transistor comprises a second channel layer and a second gate structure abutting the second channel layer;
forming a second dielectric bonding layer covering a top surface of the second gate structure, wherein a second conductive bonding structure is formed through the second dielectric bonding layer and electrically connected to the second transistor; and
bonding the first dielectric bonding layer to the second dielectric bonding layer and bonding the first conductive bonding structure to the second conductive bonding structure.

18. The method for forming a semiconductor structure as claimed in claim 17, further comprising:
removing the second substrate after bonding the first dielectric bonding layer to the second dielectric bonding layer;
forming a second backside via electrically connected to the second transistor; and
forming a second interconnect structure electrically connected to the second backside via, wherein the second interconnect structure and the first transistor are at opposite sides of the second transistor.

19. The method for forming a semiconductor structure as claimed in claim 18, further comprising:
bonding a carrier substrate to the second interconnect structure;
removing the first substrate after bonding the carrier substrate;
forming a first backside via electrically connected to the first transistor; and
forming a first interconnect structure electrically connected to the first backside via.

20. The method for forming a semiconductor structure as claimed in claim 17, wherein forming the first conductive bonding structure through the first dielectric bonding layer further comprises:
forming an opening in the first dielectric bonding layer to expose the top surface of the first gate structure; and
selectively depositing a first bonding pad in the opening.
